(19) United States
(12) Patent Application Publication
(10) Pub. No.: US 2026/0075968 A1
(43) Pub. Date: Mar. 12, 2026

(54) IMAGE SENSOR AND MANUFACTURING METHOD THEREOF

(71) Applicant: Samsung Electronics Co., Ltd., Suwon-si (KR)

(72) Inventors: Yunhyeok KIM, Suwon-si (KR); Masato FUJITA, Suwon-si (KR); Seungki BAEK, Suwon-si (KR); Kyungduck LEE, Suwon-si (KR)

(73) Assignee: Samsung Electronics Co., Ltd., Suwon-si (KR)

(21) Appl. No.: 19/251,103

(22) Filed: Jun. 26, 2025

(30) Foreign Application Priority Data
Sep. 6, 2024 (KR) 10-2024-0121523

(51) Int. Cl. H10F 39/00; H10F 39/18

(52) U.S. Cl. CPC H10F 39/80373; H10F 39/014; H10F 39/182

(57) ABSTRACT

The present disclosure relates to an image sensor and a manufacturing method of the same. A manufacturing method of an image sensor may include performing a first etching process to form a first gate recess in a first active region of a substrate, performing a second etching process to form a second gate recess in a second active region of the substrate, and forming a gate dielectric film on an inner surface of the first gate recess and an inner surface of the second gate recess, wherein the second etching process may be also performed on at least a portion of the first gate recess so that a depth of the at least a portion of the first gate recess becomes larger, and the depth of the at least a portion of the first gate recess is larger than a depth of the second gate recess.

### CROSS-REFERENCE TO RELATED APPLICATION(S)

This U.S. non-provisional application claims priority under 35 USC § 119 to Korean Patent Application No. 10-2024-0121523, filed on Sep. 6, 2024, in the Korean Intellectual Property Office, the disclosure of which is herein incorporated by reference in its entirety.

### BACKGROUND

The present disclosure relates to an image sensor and a manufacturing method of the same.

An image sensor is a sensor including a semiconductor element that converts an optical image into an electrical signal. Recently, with the development of the computer and communication industries, the demand for image sensors with improved performance has increased in various fields such as digital cameras, camcorders, Personal Communication System (PCS), gaming devices, security cameras, medical micro cameras, and/or the like. The image sensors can be classified into a type of image sensor, such as a charge coupled device (CCD) type or a complementary metal oxide semiconductor (CMOS) type. The CMOS type image sensor is provided with a plurality of pixels arranged two-dimensionally. Each of the pixels includes a photodiode (PD). The photodiode serves to convert incident light into an electrical signal.

### SUMMARY

One object of the present disclosure is directed to providing an image sensor and a manufacturing method of the image sensor, which can simplify manufacturing processes and reduce manufacturing costs.

Another object of the present disclosure is directed to providing an image sensor and a manufacturing method of the image sensor, which can minimize misalignment.

A manufacturing method of an image sensor according to at least one embodiment of the present disclosure may include providing a substrate, forming a first gate recess in a first active region of the substrate using a first etching process, forming a second gate recess in a second active region of the substrate using a second etching process, and forming a gate dielectric film on an inner surface of the first gate recess and an inner surface of the second gate recess, wherein the second etching process may be also performed on at least a portion of the first gate recess such that a depth of the at least a portion of the first gate recess becomes larger, and such that the depth of the at least a portion of the first gate recess, in the substrate, is larger than a depth of the second gate recess.

The manufacturing method may further include sequentially forming a lower hard mask film and an upper hard mask film on the substrate, forming a first upper opening and a second upper opening in the upper hard mask film, and forming a lower opening overlapping a portion of the first upper opening in the lower hard mask film, wherein the forming of the first gate recess includes etching the substrate through the first etching process using the lower hard mask film having the lower opening as an etching mask.

The remaining portion of the first upper opening may expose an upper surface of a first portion of the lower hard mask film, and the second upper opening may expose an upper surface of a second portion of the lower hard mask film, and the forming of the first gate recess may further include etching the first portion and the second portion of the lower hard mask film through the first etching process using the upper hard mask film as an etching mask.

The lower hard mask film may include a first lower recess formed by etching the first portion of the lower hard mask film, and a second lower recess formed by etching the second portion of the lower hard mask film, and the forming of the second gate recess may include etching the substrate through the second etching process using the upper hard mask film having the first upper opening and the second upper opening and the lower hard mask film having the first lower recess and the second lower recess as etching masks.

The first gate recess may include a first recess region and a second recess region, the first recess region may be formed under the portion of the first upper opening overlapping the lower opening, and the second recess region may be formed under the remaining portion of the first upper opening.

A depth of the first recess region may be larger than a depth of the second recess region.

A bottom of the second recess region and a bottom of the second gate recess may be at a substantially same level.

The forming of the lower opening may include forming a mask pattern on the upper hard mask film having the first and second upper openings, the mask pattern having an opening defining the lower opening and covering at least a portion of the first and second portions of the upper hard mask film, and etching the lower hard mask film using the mask pattern as an etching mask.

The second recess region may be formed by sequentially etching the mask pattern, the first portion of the lower hard mask film, and the substrate, and the second gate recess may be formed by sequentially etching the mask pattern, the second portion of the lower hard mask film, and the substrate.

A manufacturing method of an image sensor according to at least one embodiment of the present disclosure may include sequentially forming a lower hard mask film and an upper hard mask film on a substrate, forming a first upper opening and a second upper opening in the upper hard mask film, forming a first lower opening in the lower hard mask film such that the first lower opening overlaps a portion of the first upper opening, and forming a first gate recess and a second gate recess in the substrate by etching the lower hard mask film having the first lower opening and etching the substrate using the upper hard mask film having the first and second upper openings as an etching mask.

The first gate recess may include a first recess region and a second recess region, the first recess region is formed under the portion of the first upper opening overlapping the first lower opening, and the second recess region is formed under the remaining portion of the first upper opening.

The forming of the first lower opening may include forming spacers on inner surfaces of the first and second upper openings, and etching the lower hard mask film using the upper hard mask film and the spacers as etching masks.

The manufacturing method may further include, before forming the lower hard mask film, forming a shallow element isolation pattern in the substrate to define a first active region and second active region, wherein forming the first lower opening includes forming a second lower opening in the lower hard mask layer such that the second lower opening overlaps the second upper opening, the first lower opening may expose a portion of the first active region, the second lower opening may expose the shallow element isolation pattern, the first gate recess may be formed in the first active region, and the second gate recess may be formed in the second active region.

The first gate recess may include a first recess region and a second recess region, the first recess region may be formed in the portion of the first active region exposed by the first lower opening, the second recess region may be formed in another portion of the first active region, and a level of a bottom of the second recess region may be higher than a level of a bottom of the first recess region and substantially the same as a level of a bottom of the second gate recess.

The manufacturing method may further include forming a floating diffusion region in the substrate, forming a gate dielectric film conformally covering inner surfaces of the first and second gate recesses, and on the gate dielectric film, forming a transfer gate filling the first gate recess and a source follower gate filling the second gate recess, wherein the second recess region may be formed between the first recess region and the floating diffusion region.

An image sensor according to at least one embodiment of the present disclosure may include a shallow element isolation pattern in a substrate, the shallow element isolation pattern defining a first active region and a second active region, a transfer gate filling a first gate recess in the first active region, a source follower gate filling a second gate recess in the second active region, and a gate dielectric film between the transfer gate and an inner surface of the first gate recess and between the source follower gate and an inner surface of the second gate recess, wherein the first gate recess may include a first recess region and a second recess region shallower than the first recess region, and wherein a bottom of the second recess region and a bottom of the second gate recess are at a substantially same level.

The bottom of the second recess region may include at least one of a flat surface or an inflection point.

The second gate recess may include a pair of second gate recesses that are formed in the second active region the pair of second gate recesses may be spaced apart from each other, and a fin-shaped channel region may be between the pair of second gate recesses.

One side surface of the second gate recess may be defined by the shallow element isolation pattern and the other side surface of the second gate recess may be defined by the second active region, and a channel region, configured to be controlled by the source follower gate, may be adjacent to the other side surface of the second gate recess and a portion of an upper surface of the second active region.

A channel region under the source follower gate may be concave along a bottom surface of the second gate recess.

### BRIEF DESCRIPTION OF DRAWINGS

FIG. 1 is a block diagram of an image sensor according to some embodiments of the present disclosure.

FIG. 2 is a circuit diagram of pixels included in a pixel array of an image sensor according to some embodiments of the present disclosure.

FIG. 3 is a circuit diagram of pixels included in a pixel array of an image sensor according to at least one embodiment of the present disclosure.

FIG. 4 is a plan view of an image sensor according to at least one embodiment of the present disclosure.

FIG. 5 is an enlarged plan view of one active portion group of FIG. 4.

FIG. 6 is a cross-sectional view taken along line A-A′ of FIG. 5.

FIG. 7 is a flowchart showing a manufacturing method of an image sensor according to at least one embodiment of the present disclosure.

FIG. 8 is a flowchart showing a manufacturing method of an image sensor according to at least one embodiment of the present disclosure.

FIGS. 9 to 18 show a manufacturing method of an image sensor according to at least one embodiment of the present disclosure, which are cross-sectional views corresponding to line I-I′ of FIG. 5,

FIGS. 19 to 21 show parts of a manufacturing method of an image sensor according to at least one embodiment of the present disclosure, which are cross-sectional views corresponding to line I-I′ of FIG. 5.

FIGS. 22 to 27 show a manufacturing method of an image sensor according to at least one embodiment of the present disclosure, which are cross-sectional views corresponding to line I-I′ of FIG. 5,

FIG. 28 is a plan view of an active portion group according to at least one embodiment of the present disclosure.

FIG. 29 is a cross-sectional view taken along line II-II′ of FIG. 28.

FIG. 30 is a plan view of an active portion group according to at least one embodiment of the present disclosure.

FIG. 31 is a cross-sectional view taken along line III-III′ of FIG. 30.

FIG. 32 is a cross-sectional view of an image sensor according to at least one embodiment of the present disclosure.

FIG. 33 is a cross-sectional view of an image sensor according to at least one embodiment of the present disclosure.

### DETAILED DESCRIPTION

Hereafter, the embodiments of the present disclosure will be clearly and thoroughly described with reference to the accompanying drawings. When describing the example embodiments with reference to the accompanying drawings, like reference numerals refer to like elements and a repeated description related thereto may be omitted. In the drawings, sizes of components in the drawings may be exaggerated for convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Also, functional elements, unless indicated otherwise, may be implemented by and/or controlled via processing circuitry such as hardware, software, and/or a combination of a hardware and a software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

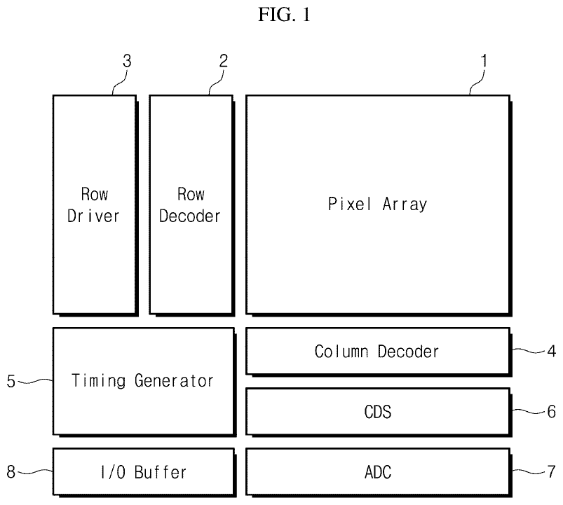

FIG. 1 is a block diagram of an image sensor according to some embodiments of the present disclosure.

Referring to FIG. 1, the image sensor according to some embodiments of the present invention includes a pixel array 1, a row decoder 2, a row driver 3, a column decoder 4, a timing generator 5, a correlated double sampler (CDS) 6, an analog to digital converter (ADC) 7, and an input/output buffer (I/O buffer) 8. Components of the image sensor may communicate with one another to send and/or receive information such as but not limited to data and/or commands. The information may be sent and/or received in a broadcast manner, or a one-way manner, or a two-way manner, and may be sent and/or received in a serial and/or parallel manner, and may be encoded in a digital and/or analog fashion. Example embodiments are not limited thereto.

The pixel array 1 may include a plurality of pixels arranged two-dimensionally, and the pixels may be configured to convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the correlated double sampler 6.

The row driver 3 may provide the pixel array 1 with a plurality of driving signals for driving the plurality of pixels based on the result of decoding in the row decoder 2. When the pixels are arranged in a matrix form, the driving signals may be provided in a row unit.

The timing generator 5 may be configured to provide timing signals and control signals to the row decoder 2 and the column decoder 4.

The correlated double sampler 6 may receive the electrical signals generated from the pixel array 1 and may be configured to hold and sample the received signals. The correlated double sampler 6 may double-sample a specific noise level and a signal level caused by an electrical signal to output a difference level corresponding to the difference between the noise level and the signal level.

The analog to digital converter 7 may be configured to convert an analog signal corresponding to the difference level output from the correlated double sampler 6 into a digital signal and may output the digital signal.

The input/output buffer 8 may latch the digital signals and sequentially output the latched signals to an image signal processor (not shown) based on the result of decoding in the column decoder 4.

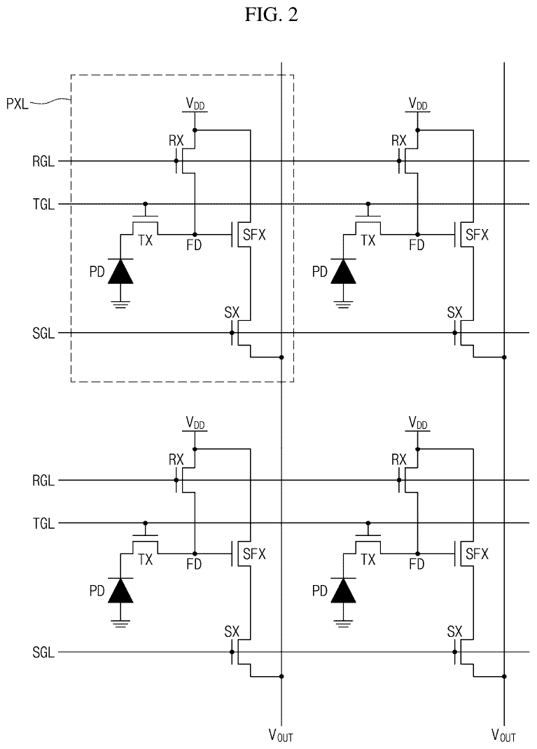

FIG. 2 is a circuit diagram of pixels included in a pixel array of an image sensor according to some embodiments of the present disclosure.

Referring to FIG. 2, a pixel array may include a plurality of pixels PXL, and the pixels PXL may be arranged in a matrix form. Each of the pixels PXL may include pixel transistors, and the pixel transistors may include a transfer transistor TX and logic transistors RX, SX, and SFX. The logic transistors RX, SX, and SFX may include a reset transistor RX, a selection transistor SX, and a source follower transistor SFX. In addition, each of the pixels PXL may include a photoelectric conversion element PD and a floating diffusion region FD.

The photoelectric conversion element PD may generate and accumulate photocharges in proportion to an amount of light incident from the outside. The photoelectric conversion element PD may include a photodiode, a phototransistor, a photogate, a pinned photodiode, a combination thereof, and/or the like. The transfer transistor TX may be configured to transfer the photocharges generated from the photoelectric conversion element PD to the floating diffusion region FD when, e.g., the transfer transistor TX is in an on-state. A transfer gate of the transfer transistor TX may be connected to a transfer gate line TGL. The floating diffusion region FD may be configured to receive and cumulatively store the photocharges generated from the photoelectric conversion element PD.

A gate of the source follower transistor SFX may be connected to the floating diffusion region FD. A drain terminal of the source follower transistor SFX may be connected to a power terminal V_{DD} that may receive a power voltage. The source follower transistor SFX may be controlled according to the amount of photocharges accumulated in the floating diffusion region FD. The source follower transistor SFX may be configured to convert a signal corresponding to the amount of input photocharges into a voltage signal.

The reset transistor RX may be configured to reset the charges accumulated in the floating diffusion region FD. The reset transistor RX may periodically receive a reset signal and, thereby may periodically reset the charges accumulated in the flowing diffusion region FD based on the reset signal. For example, a gate of the reset transistor RX may be connected to a reset gate line RGL; a source terminal of the reset transistor RX may be connected to the floating diffusion region FD; and a drain terminal of the reset transistor RX may be connected to the power terminal V_{DD}. When the reset transistor RX is turned on, the power voltage of the power terminal V_{DD} may be applied to the floating diffusion region FD through the reset transistor RX. In other words, when the reset transistor RX is turned on, the charges accumulated in the floating diffusion region FD may be discharged by the power voltage, thereby resetting the floating diffusion region FD.

The source follower transistor SFX may be configured to serve as a source follower buffer amplifier. The source follower transistor SFX may amplify a change in potential in the floating diffusion region FD and output the change in amplified potential to an output line V_{OUT}.

A gate of the selection transistor SX may be connected to a selection gate line SGL. A drain terminal of the selection transistor SX may be connected to the source terminal of the source follower transistor SFX, and a source terminal of the selection transistor SX may be connected to the output line V_{OUT}. The selection transistors SX of the pixels PXL to be readout in row units may be selected by a selection signal applied through a corresponding selection gate line SGL. When the selection transistor SX is turned on, the change in potential amplified by the source follower transistor SFX may be output to the output line V_{OUT} through the selection transistor SX.

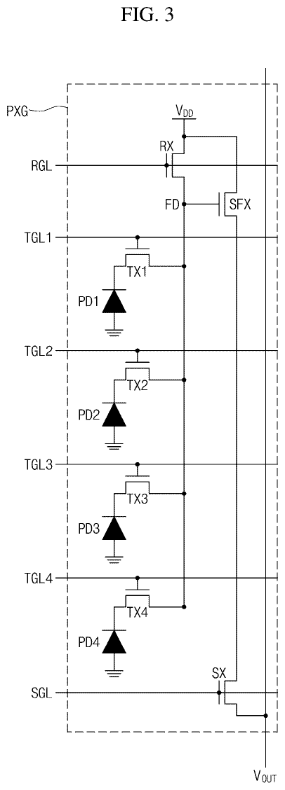

FIG. 3 is a circuit diagram of pixels included in a pixel array of an image sensor according to at least one embodiment of the present disclosure.

Referring to FIG. 3, the pixel array may include a plurality of pixel groups PXG, and each of the pixel groups PXG may include a plurality of pixels. A circuit diagram of one pixel group PXG is shown in FIG. 3.

Referring to FIG. 3, in at least one embodiment, the pixel group PXG may include a plurality of pixels (e.g., first to fourth pixels). The first to fourth pixels may include first to fourth transfer transistors TX1, TX2, TX3, and TX4 and first to fourth photoelectric conversion elements PD1, PD2, PD3, and PD4, respectively. Gates of the first to fourth transfer transistors TX1, TX2, TX3, and TX4 may be respectively connected to first to fourth transfer gate lines TGL1, TGL2, TGL3, and TGL4. The first to fourth pixels may share the reset transistor RX, the source follower transistor SFX, and the selection transistor SX previously described.

In the embodiments of FIG. 3, the pixel group PXG includes four pixels, but the embodiments of the present disclosure are not limited thereto. The number of pixels in the pixel group PXG may be changed. For example, the number of pixels in the pixel group PXG may be eight. Accordingly, the number of transfer transistors and the number of photoelectric conversion elements may be, respectively, changed.

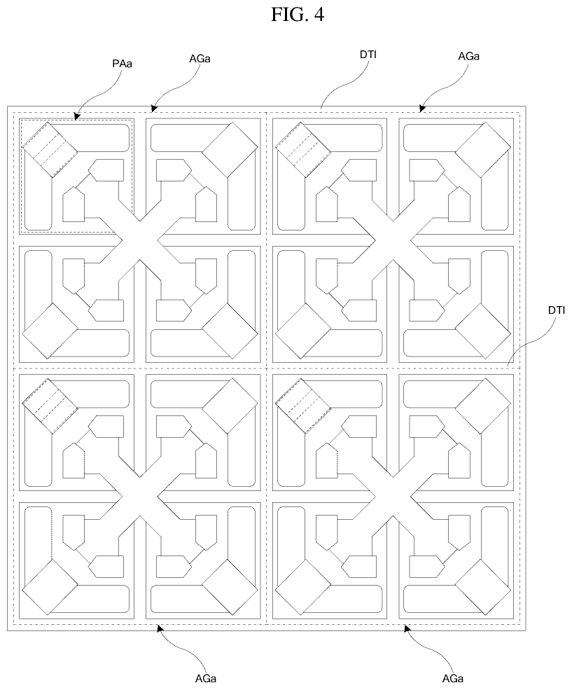

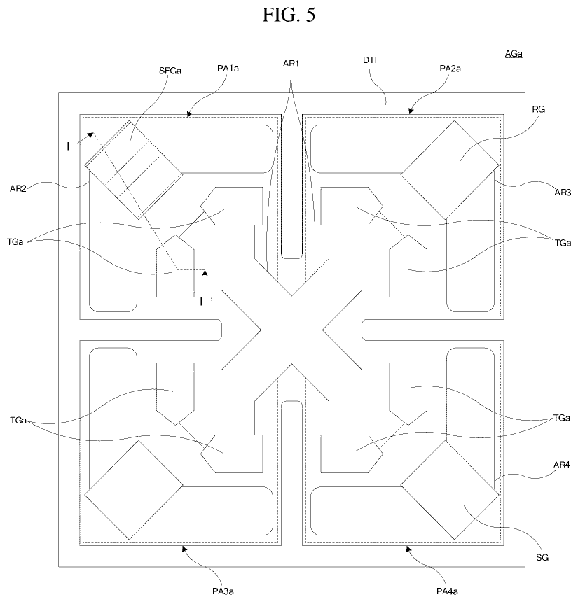

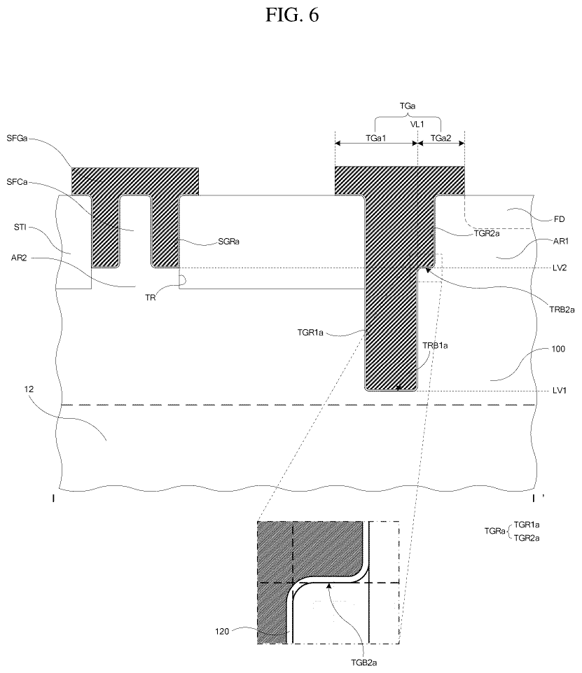

FIG. 4 is a plan view of an image sensor according to at least one embodiment of the present disclosure. FIG. 5 is an enlarged plan view of one active portion group AGa of FIG. 4. FIG. 6 is a cross-sectional view taken along line I-I′ of FIG. 5.

Referring to FIGS. 4, 5, and 6, a deep element isolation pattern DTI is provided in a substrate 100 to define pixel active portions PAa. In at least one embodiment, each of the pixel active portions PAa may be a portion of the substrate 100 surrounded by the deep element isolation pattern DTI in a plan view. In at least one embodiment, a plurality of adjacent pixel active portions PAa may form an active portion group AGa. In other words, a plurality of active portion groups AGa may be defined by the deep element isolation pattern DTI. Each of the active portion groups AGa may be a portion of the substrate 100 in which the pixel group PXG shown in FIG. 3 is formed. In these cases, the photoelectric conversion elements PD1 to PD4 of the pixel group PXG in FIG. 3 may be respectively provided in the pixel active portions PAa of the active portion group AGa, and the transfer transistors TX1 to TX4 of the pixel group PXG in FIG. 3 may be respectively provided in and on the pixel active portions PAa of the active portion group AGa, and the logic transistors RX, SFX, and SX of the pixel group PXG in FIG. 3 may be provided in and on one of the pixel active portions PAa of the active portion group AGa. Alternatively, the pixel PXL of FIG. 2 may be formed in and on each of the pixel active portions PAa. In these cases, the active portion group AGa may be omitted, and the photoelectric conversion element PD of the pixel PXL in FIG. 2 may be provided in each of the pixel active portions PAa, and the pixel transistors TX, RX, SFX, and SX of the pixel PXL in FIG. 2 may be provided in and on each of the pixel active portions PAa. Hereafter, for convenience of explanation, a case in which the pixel group PXG of FIG. 3 is provided in and on the active portion group AGa will be described as an example.

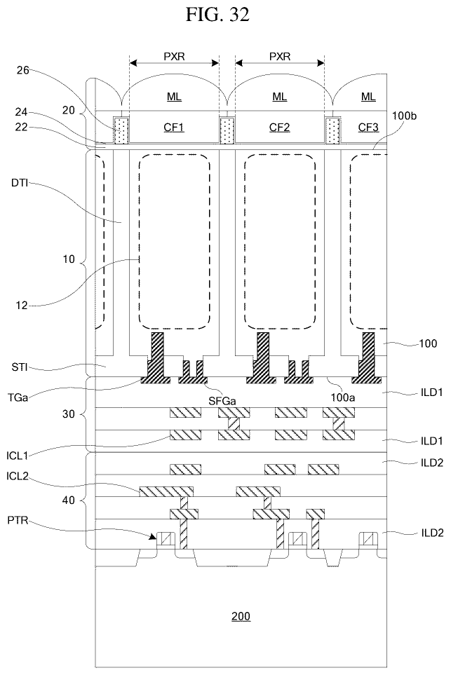

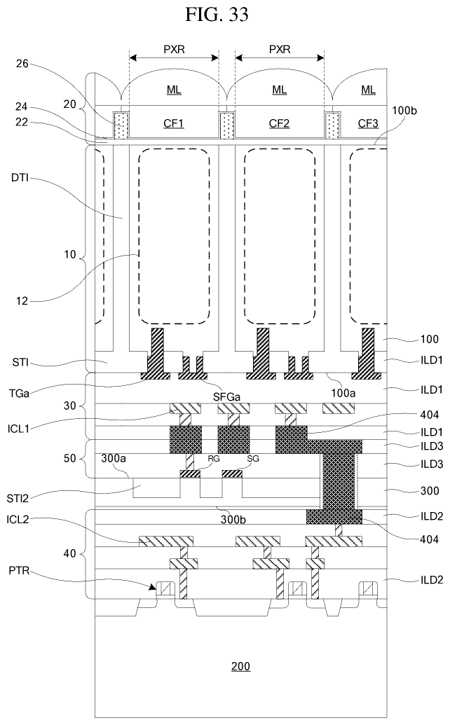

The substrate 100 may have one (e.g., a first) surface and another (e.g., a second) surface opposite to the one surface. The one surface of the substrate 100 may be a front surface of the substrate 100, and the other surface of the substrate 100 may be a back surface of the substrate 100. The one surface of the substrate 100 may correspond to a first surface 100a of a first substrate 100 in FIG. 32 or FIG. 33 described below, and the other surface of the substrate 100 may correspond to a second surface 100b of the first substrate 100 in FIG. 32 or FIG. 33. In other words, the substrate 100 in FIG. 6 may be a flipped state compared to the first substrate 100 in FIG. 32 or FIG. 33.

In at least one embodiment, the deep element isolation pattern DTI may pass through the substrate 100. In other words, the deep element isolation pattern DTI may fill deep trenches that pass through the substrate 100. The deep element isolation pattern DTI may form a substantial grid shape in a plan view.

A shallow element isolation pattern STI is provided in the substrate 100 to define a plurality of active regions in each of the active portion groups AGa. The shallow element isolation pattern STI may fill a shallow trench recessed from the one surface of the substrate 100. In other words, the shallow element isolation pattern STI may be provided in the substrate 100 and may be adjacent to the one surface of the substrate 100. Each of the active regions may be a portion of the substrate 100 (that is, a portion of the pixel active portion PAa) surrounded by the shallow element isolation pattern STI in a plan view.

The plurality of active regions may include a first active region AR1, a second active region AR2, a third active region AR3, and a fourth active region AR4. The transfer transistor TX may be provided in and/or on the first active region AR1, and the source follower transistor SFX may be provided in and/or on the second active region AR2. The reset transistor RX may be provided in and/or on the third active region AR3, and the selection transistor SX may be provided in and/or on the fourth active region AR4. More specifically, the transfer gate TGa may be disposed on the first active region AR1, and the source follower gate SFGa may be disposed on the second active region AR2. The reset gate RG may be disposed on the third active region AR3, and the selection gate SG may be disposed on the fourth active region AR4.

In some embodiments, the first active region AR1 may be defined in each of the pixel active portions PAa of the active portion group AGa. For example, as shown in FIG. 5, each of the active portion groups AGa may include the first to fourth pixel active portions PA1a to PA4a, and the first active region AR1 may be defined in each of the first to fourth pixel active portions PA1a to PA4a. In these cases, the transfer gates TGa may be respectively disposed on the first active regions AR1. In at least one embodiment, each of the first active regions AR1 of the pixel active portions PAa may extend and may be connected to each other.

In some embodiments, the second active region AR2 may be located in any one of the pixel active portions PAa of the active portion group AGa. For example, as shown in FIG. 5, the second active region AR1 may be defined in the first pixel active portion PA1a.

In at least one embodiment, the third active region AR3 may be defined in another one of the pixel active portions PAa of the active portion group AGa, and the fourth active region AR4 may be defined in still another one of the pixel active portions PAa of the active portion groups AGa. For example, as shown in FIG. 5, the third active region AR3 may be defined in the second pixel active portion PA2a, and the fourth active region AR4 may be defined in the fourth pixel active portion PA4a. In at least one embodiment, an additional transistor may be provided in and on another active region defined in the third active region PA3a. The additional transistor may be a dummy transistor, or a transistor (for example, a dual conversion gain transistor) configured to perform an additional function.

The floating diffusion region FD may be provided in the first active region AR1 at one side of the transfer gate TGa. Each of the floating active regions FD of the active portion groups AGa may extend along the first active regions AR1 and may be connected to each other.

A photoelectric conversion region 12 may be provided in each of the pixel active portions PAa. The substrate 100 (that is, each of the pixel active portions PAa) may be doped with impurities having a first conductivity type, and the photoelectric conversion region 12 may be doped with impurities having a second conductivity type different from the first conductivity type. For example, one of the first conductivity type and the second conductivity type may be a P-type, and the other of the first conductivity type and the second conductivity type may be an N-type. For example, the first conductivity type may be the P-type, and the second conductivity type may be the N-type. Accordingly, the photoelectric conversion region 12 and the pixel active portion PAa surrounding the photoelectric conversion region 12 may form a photodiode by being a PN-junctioned diode. The floating diffusion region FD may be doped with impurities having the second conductivity type.

Referring back to FIG. 6, a first gate recess TGRa may be provided in the first active region AR1. Specifically, the first gate recess TGRa may be recessed from a portion of an upper surface of the first active region AR1 (that is, a portion of the one surface of the substrate 100).

A bottom of the first gate recess TGRa may have bottoms provided at different depths. In at least one embodiment, the bottoms of the first gate recess TGRa may include flat surfaces.

More specifically, the first gate recess TGRa may include a first recess region TGR1a and a second recess region TGR2a that have different depths. A bottom TRB1a of the first recess region TGR1a may be located at a first level LV1, and a bottom TRB2a of the second recess region TGR2a may be located at a second level LV2 different from the first level LV1. In at least one embodiment, the first level LV1 is lower than the second level LV2. In other words, the bottom TRB1a of the first recess region TGR1a may be deeper than the bottom TRB2a of the second recess region TGR2a.

The first recess region TGR1a and the second recess region TGR2a may be distinguished by a change in heights of the bottoms TRB1a and TRB2a. For example, the first recess region TGR1a and the second recess region TGR2a may be distinguished based on an imaginary vertical line VL1 at which a level of the bottom changes from the first level LV1 to the second level LV2. In other words, the first recess region TGR1a may be provided at one side of the imaginary vertical line VL1, and the second recess region TGR2a may be provided at the other side of the imaginary vertical line VL1. In at one embodiment, the bottom TRB1a of the first recess region TGR1a and/or the bottom TRB2a of the second recess region TGR2a may include a flat surface.

The bottom of the first gate recess TGRa may become nonlinearly shallower as the bottom of the first gate recess TGRa approaches the floating diffusion region FD. In at least one embodiment, the second recess region TGR2a may be located between the first recess region TGR1a and the floating diffusion region FD. Through this, one side surface of the first gate recess TGRa adjacent to the floating diffusion region FD may have a slope, a curved surface and/or a step. The slope may have a constant gradient, and the curved surface may have a gradient which varies based on the distance from the floating diffusion region FD, and/or a step. That is, in the first gate recess TGRa, a slope of the one side surface adjacent to the floating diffusion region FD may be gentler than a slope of the other side surface. Accordingly, the photocharge transfer performance of the transfer transistor can be improved.

The first recess region TGR1a and the second recess region TGR2a may be connected. In at least one embodiment, the bottom TRB2a of the second recess region TGR2a may be connected to an upper end of one side surface of the first recess region TGR1a. In at least one embodiment, a connection portion between the bottom TRB2a of the second recess region TGR2a and the one side surface of the first recess region TGR1a may be curved. The one side surface of the first recess region TGR1a may be a lower portion of the one side surface of the first gate recess TGRa.

Furthermore, a connection portion between the bottom TRB2a of the second recess region TGR2a and the one side surface of the second recess region TGR2a may also be curved. The one side surface of the second recess region TGR2a may be adjacent to the floating diffusion region FD. The one side surface of the second recess region TGR2a may be an upper portion of the one side surface of the first gate recess TGRa.

The first recess region TGR1a may be adjacent to the photoelectric conversion region 12. Specifically, the bottom TRB1a of the first recess region TGR1a may be adjacent to the photoelectric conversion region 12. Compared to the bottom TRB1a of the first recess region TGR1a, the bottom TRB2a of the second recess region TGR2a may be spaced farther apart from the photoelectric conversion region 12.

A depth of the first recess region TGR1a may be greater than a depth of a trench TR filled by the shallow element isolation pattern STI. In other words, the bottom TRB1a of the first recess region TGR1a may be deeper than a bottom of the trench TR.

A depth of the second recess region TGR2a may be shallower than the depth of the trench TR filled with the shallow element isolation pattern STI. Specifically, the bottom TRB2a of the second recess region TGR2a may be located shallower than the bottom of the trench TR in a depth direction of the substrate 100. However, the present disclosure is not limited thereto, and the bottom TRB2a of the second recess region TGR2a may also be located deeper than the bottom of the trench TR in the depth direction of the substrate 100.

The transfer gate TGa may fill the first gate recess TGRa. Specifically, the transfer gate TGa may fill the first gate recess TGRa located in the first active region AR1. In addition, the transfer gate TGa may protrude upward from the one surface (e.g., an upper surface) of the substrate 100. The transfer gate TGa may extend planarly on the upper surface of the substrate 100. Therefore, the transfer gate TGa may cover a portion of the first active region AR1 and a portion of the shallow element isolation pattern STI.

The transfer gate TGa may include a first gate portion TGa1 filling the first recess region TGR1a and a second gate portion TGa2 filling the second recess region TGR2a. The first gate portion TGa1 and the second gate portion TGa2 may be distinguished based on the imaginary vertical line VL1.

A gate dielectric film 120 may be provided on the inner surface of the first gate recess TGRa. The gate dielectric film 120 may be disposed between the transfer gate TGa and the first gate recess TGRa. The gate dielectric film 120 may be formed conformally. The gate dielectric film 120 may separate the transfer gate TGa from the substrate 100.

The transfer gate TGa may be provided adjacent to the floating diffusion region FD. The second gate portion TGa2 may be located between the first gate portion TGa1 and the floating diffusion region FD. The first gate portion TGa1 and the second gate portion TGa2 may be provided integrally.

A second gate recess SGRa may be provided in the second active region AR2. Specifically, the second gate recess SGRa may be recessed from one surface of the substrate 100 located in the second active region AR2.

In at least one embodiment, the second gate recess SGRa may include a pair of second gate recesses SGRa that are spaced apart from each other. A channel region SFCa may be defined between the pair of second gate recesses SGRa that are spaced apart from each other. The channel region SFCa may be defined in a fin-shape between the pair of second gate recesses SGRa.

A depth of the second gate recess SGRa may be the same as (or substantially similar to) the depth of the second recess region TGR2a. Specifically, a bottom SRBa of the second gate recess SGRa and the bottom TRB2a of the second recess region TGR2a may be located at substantially the same level. For example, the bottom SRBa of the second gate recess SGRa and the bottom TRB2a of the second recess region TGR2a may be located at the second level LV2.

The depth of the second gate recess SGRa may be smaller than the depth of the first recess region TGR1a. Specifically, the bottom TRB1a of the first recess region TGR1a may be located at the first level LV1, and the bottom SRBa of the second gate recess SGRa may be located at the second level LV2 that is smaller than the first level LV1.

A source follower gate SFGa may fill the second gate recess SGRa. Specifically, the source follower gate SFGa may fill the second gate recess SGRa located in the second active region AR2. In at least one embodiment, the source follower gate SFGa may fill the pair of second gate recesses SGRa. The source follower gate SFGa may protrude upward from the upper surface of the substrate 100. The source follower gate SFGa may extend planarly on the upper surface of the substrate 100. Therefore, the source follower gate SFGa may cover the channel region SFCa and a portion of the shallow element isolation pattern STI.

The gate dielectric film 120 may be provided on an inner surface of the second gate recess SGRa. In at least one embodiment, the gate dielectric film 120 may be provided on the inner surfaces of the pair of second gate recesses SGRa and the channel region SFCa. The gate dielectric film 120 may be disposed between the source follower gate SFGa and the inner surface of the second gate recess SGRa and between the source follower gate SFGa and the channel region SFCa. The gate dielectric film 120 may be formed conformally. The gate dielectric film 120 may separate and electrically isolate the source follower gate SFGa from the substrate 100.

In at least one embodiment, gates TG, SFG, RG, and SG may be formed of the same conductive material. For example, the gates TG, SFG, RG, and SG may include at least one of a doped semiconductor material (e.g., doped polysilicon), a metal (e.g., tungsten, titanium, aluminum, tantalum, etc.), a conductive metal nitride (e.g., titanium nitride, tantalum nitride, etc.), or a conductive metal-semiconductor compound (e.g., metal silicide, etc.). In at least one embodiment, the conductive material may be a zero-bandgap material and/or a material having conductivity in the range of a zero bandgap material.

Meanwhile, in the above-described embodiments, each of the active portion groups AGa may include a plurality of pixel active portions PAa. However, the embodiments of the present disclosure are not limited thereto. In at least one embodiment, each of the active portion groups AGa may have a single pixel active portion PAa. In these cases, the active portion group AGa may correspond to the pixel active portion PAa, and the deep element isolation pattern DTI may not extend into each of the active portion groups AGa. In this case, the above-described first to fourth active regions AR1 to AR4 may be defined in each of the pixel active portions PAa. In other words, the pixel transistors TX, RX, SFX, and SX, the floating diffusion FD, and the photoelectric conversion element PD may be formed in each of the pixel active portions PAa. In these cases, the image sensor of FIG. 2 may be implemented.

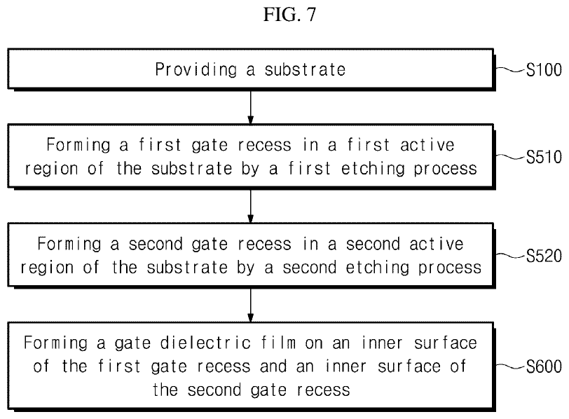

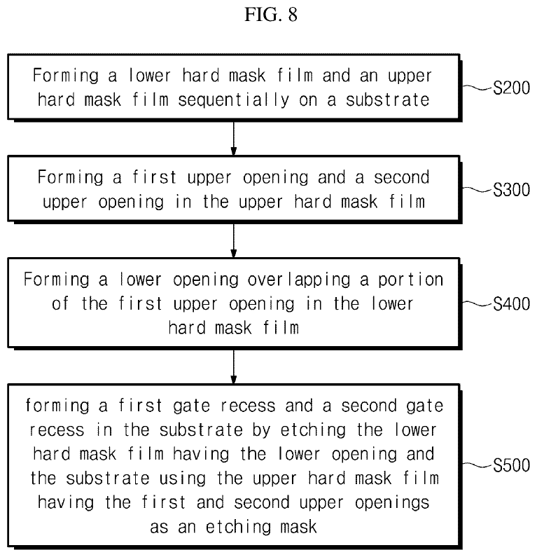

FIG. 7 is a flowchart showing a manufacturing method of an image sensor according to at least one embodiment of the present disclosure. FIG. 8 is a flowchart showing a manufacturing method of an image sensor according to at least one embodiment of the present disclosure.

Referring to FIG. 7, a manufacturing method of an image sensor (hereinafter, referred to as “manufacturing method”) may include providing a substrate (S100), performing a first etching process to form a first gate recess in a first active region of the substrate (S510), performing a second etching process to form a second gate recess in a second active region of the substrate (S520), and forming a gate dielectric film on an inner surface of the first gate recess and an inner surface of the second gate recess (S600).

Referring to FIG. 8, a manufacturing method may further include sequentially forming a lower hard mask film and an upper hard mask film on the substrate (S200), forming a first upper opening and a second upper opening in the upper hard mask film (S300), and forming a lower opening overlapping a portion of the first upper opening in the lower hard mask film (S400).

In at least one embodiment, a manufacturing method may include forming a first gate recess and a second gate recess in the substrate by etching the lower hard mask film having the lower opening and the substrate using the upper hard mask film having the first and second upper openings as an etching mask (S500). The forming of the first gate recess and the second gate recess (S500) may include performing a first etching process to form the first gate recess in the first active region of the substrate (S510) and performing a second etching process to form the second gate recess in the second active region of the substrate (S520).

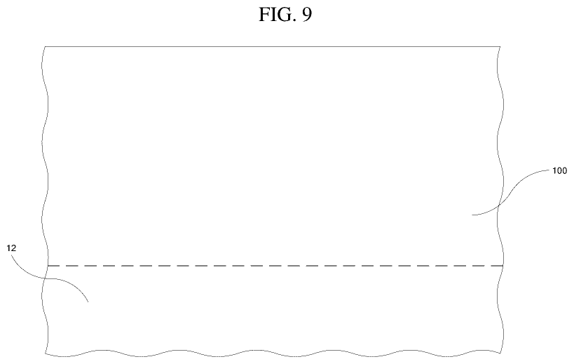

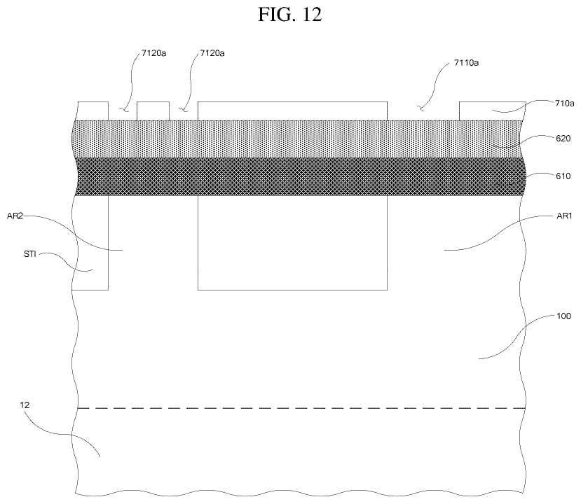

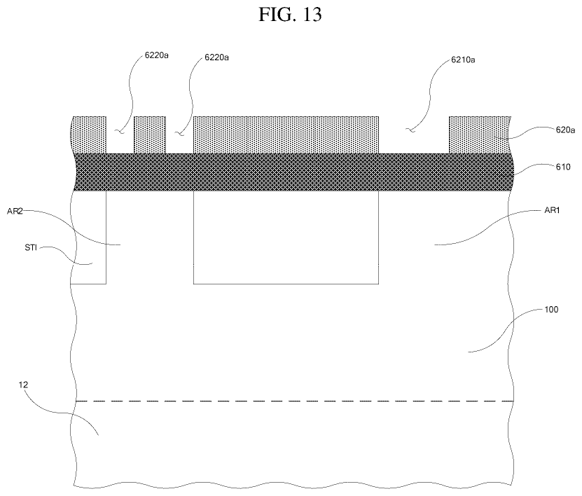

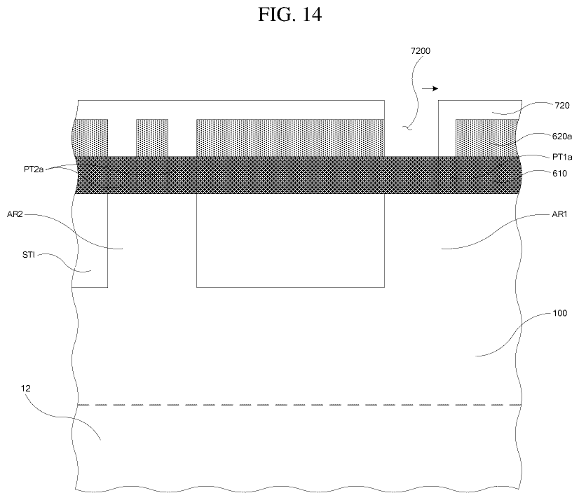

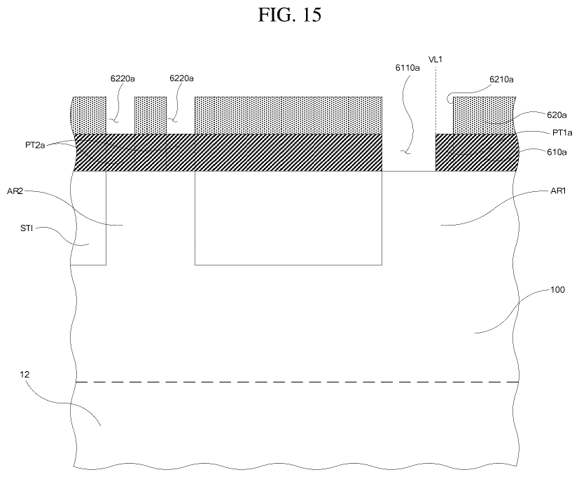

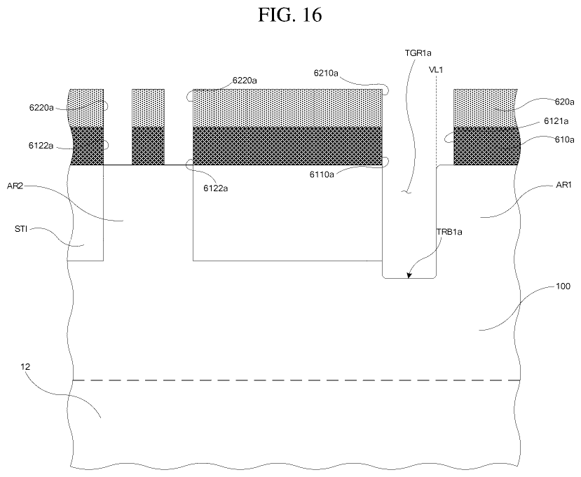

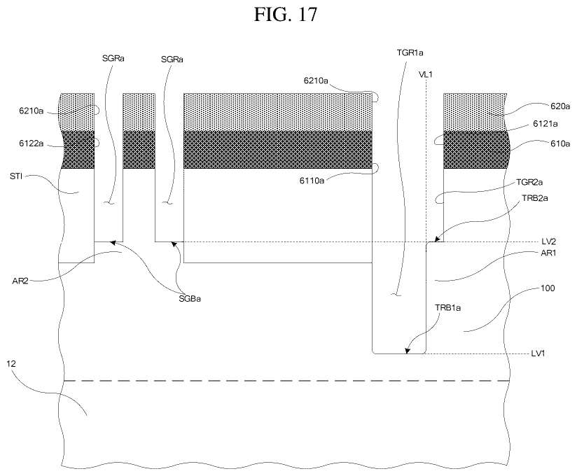

Hereafter, the manufacturing method will be described in more detail with reference to FIGS. 9 to 18.

FIGS. 9 to 18 show a manufacturing method of an image sensor according to at least one embodiment of the present disclosure, which are cross-sectional views corresponding to line I-I′ of FIG. 5,

Referring to FIG. 9, a photoelectric conversion region 12 may be formed in a substrate 100. For example, the substrate 100 may be doped with impurities having a first conductivity type, and the photoelectric conversion region 12 may be formed by being doped with impurities having a second conductivity type different from the first conductivity type.

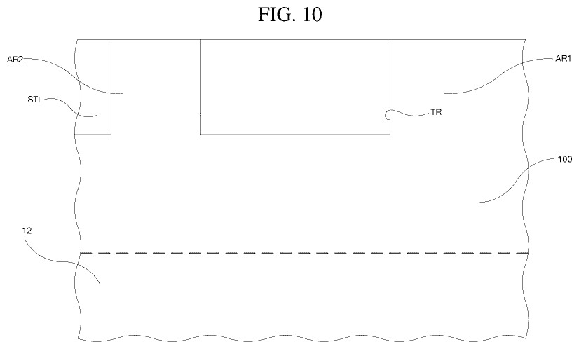

Referring to FIG. 10, a shallow element isolation pattern STI may be formed in the substrate 100 to define a first active region AR1 and a second active region AR2. Specifically, a trench TR may be formed to be recessed from one surface of the substrate 100, and the shallow element isolation pattern STI may be formed to fill the trench TR. For example, the shallow element isolation pattern STI may include an insulating material such as a silicon oxide.

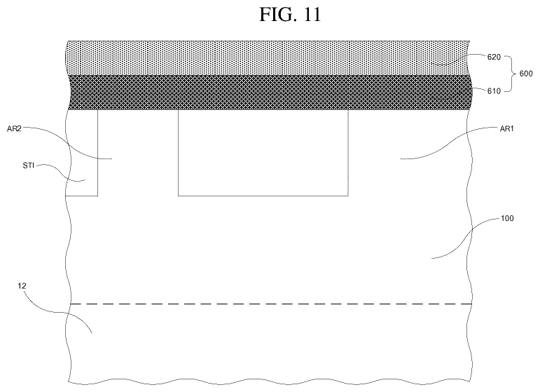

Referring to FIG. 11, a hard mask film 600 may be formed on the substrate 100 having the active regions AR1 and AR2 (S200) (see FIG. 8). In at least one embodiment, forming the hard mask film 600 may include forming, sequentially, a lower hard mask film 610 and an upper hard mask film 620 on the substrate 100. The lower and upper hard mask films 610 and 620 may cover the shallow element isolation pattern STI and the active regions AR1 and AR2.

In at least one embodiment, the lower hard mask film 610 and the upper hard mask film 620 may be made of different materials. Accordingly, the lower hard mask film 610 may have etching selectivity with respect to the upper hard mask film 620. In other words, an etch rate of the lower hard mask film 610 may differ from an etch rate of the upper hard mask film 620.

Alternatively, in at least one embodiment, the lower hard mask film 610 and the upper hard mask film 620 may be made of the same material. In these cases, the lower and upper hard mask films 610 may form a single body, the lower hard mask film 610 may be a lower portion of the hard mask film 600, and the upper hard mask film 620 may be an upper portion of the hard mask film 600.

Referring to FIGS. 7, 8, 12, and 13, first and second upper openings 6210a and 6220a may be formed in the upper hard mask film 620. The first and second upper openings 6210a and 6220a may be formed by patterning the upper hard mask film 620. Specifically, the forming of the first and second upper openings 6210a and 6220a in the upper hard mask film 620 may include forming a first mask pattern 710a having first and second openings 7110a and 7120a that define the first and second upper openings 6210a and 6220a on the upper hard mask film 620, and etching the upper hard mask film 620 using the first mask pattern 710a as an etching mask.

The first opening 7110a of the first mask pattern 710a may overlap the first active region AR1. The second opening 7120a of the first mask pattern 710a may overlap the second active region AR2. Therefore, the first upper opening 6210a formed in the upper hard mask film 620 may be located above the first active region AR1, and the second upper opening 6220a may be located above the second active region AR2.

In at least one embodiment, the etching of the upper hard mask film 620 using the etching selectivity between the upper hard mask film 620 and the lower hard mask film 610 may be performed until an upper surface of the lower hard mask film 610 is exposed. Therefore, the first upper opening 6210a may expose a portion of the lower hard mask film 610, and the second upper opening 6220a may expose another portion of the lower hard mask film 610.

In at least one embodiment, the second opening 7120a of the first mask pattern 710a may include a pair of second openings 7120a that are spaced apart from each other. The pair of second openings 7120a may overlap the second active region AR2. When the upper hard mask film 620 is etched using the first mask pattern 710a having the pair of second openings 7120a as an etching mask, a pair of second upper openings 6220a may be formed in the upper hard mask film 620. The pair of second upper openings 6220a may be located above the second active region AR2. The pair of second upper openings 6220a may expose other portions of the lower hard mask film 610.

After the first and second upper openings 6210a and 6220a are formed, the first mask pattern 710a may be removed.

Referring to FIGS. 7, 8, 14, and 15, a lower opening 6110a may be formed in the lower hard mask film 610. The lower opening 6110a may be formed by patterning the lower hard mask film 610. Specifically, the forming of the lower opening 6110a in the lower hard mask film 610 may include forming a second mask pattern 720 having a third opening 7200 that defines the lower opening 6110a on the upper hard mask film 620a, and etching the lower hard mask film 610 using the second mask pattern 720 as an etching mask.

The lower opening 6110a may overlap the first upper opening 6210a. Specifically, the lower opening 6110a may overlap a portion of the first upper opening 6210a. The remaining portion of the first upper opening 6210a may not overlap the lower opening 6110a.

To define the third opening 7200, the second mask pattern 720 may also fill the remaining portion of the first upper opening 6210a. The second mask pattern 720 filling the remaining portion of the first upper opening 6210a may also be formed on a portion of the lower hard mask film 610. The portion of the lower hard mask film 610 covered by the second mask pattern 720 filling the remaining portion of the first upper opening 6210a may be referred to as a first portion PT1a.

A portion of the second mask pattern 720 covering the first portion PT1a of the lower hard mask film 610 may cover a portion of an inner surface of the first upper opening 6210a. The third opening 7200 may be defined by the portion of the second mask pattern 720 covering the first portion PT1a of the lower hard mask film 610 and the remaining portion of the inner surface of the first upper opening 6210a.

The lower opening 6110a may not overlap the second upper opening 6220a. The second mask pattern 720 may fill the second upper opening 6220a. The second mask pattern 720 filling the second upper opening 6220a may also be formed on the other portion of the lower hard mask film 610. The other portion of the lower hard mask film 610 covered by the second mask pattern 720 filling the second upper opening 6220a may be referred to as a second portion PT2a.

In at least one embodiment, the second mask pattern 720 may fill the pair of second upper openings 6220a. In this case, the second portion PT2a may include a pair of second portions Pt2a that are spaced apart from each other.

By etching the lower hard mask film 610 using the second mask pattern 720 having the third opening 7200 as an etching mask, the lower opening 6110a may be formed in the lower hard mask film 610. The lower hard mask film 610 may be etched until the substrate 100 is exposed by the lower opening 6110a. In other words, the lower hard mask film 610 in which the lower opening 6110a is formed may expose a portion of the first active region AR1.

While forming the lower opening 6110a, the second mask pattern 720 may be etched together with the lower hard mask film 610. In at least one embodiment, the second mask pattern 720 may be removed by being etched before the lower opening 6110a is completely formed. Alternatively, in at least one embodiment, the second mask pattern 720 may be removed by a subsequent etching process after the lower opening 6110a is completely formed. In at least one embodiment, after the lower opening 6110a is completely formed, the second mask pattern 720 may be removed.

Referring to FIGS. 7, 8, and 16 to 18, a first gate recess TGRa and a second gate recess SGRa may be formed in the substrate 100. Specifically, the first and second gate recesses TGRa and SGRa may be formed by etching the substrate 100 using the upper hard mask film 620a having the first and second upper openings 6210a and 6220a as an etching mask.

The first recess region TGR1a may be formed in the substrate 100. The first recess region TGR1a may be formed by etching a portion of the first active region AR1 exposed by the lower opening 6110a by the first etching process. Therefore, the first recess region TGR1a may be formed under the lower opening 6110a. The first recess region TGR1a may be formed under a portion of the first upper opening 6210a overlapping the lower opening 6110a.

In at least one embodiment, the lower hard mask film 610a may be etched while etching the substrate 100. For example, by the first etching process, while the portion of the first active region AR1 exposed by the lower opening 6110a is etched, the lower hard mask film 610a having the lower opening 6110a may be etched. More specifically, as the second mask pattern 720 is removed, the first and second portions PT1a and PT2a of the lower hard mask film 610a are exposed by the first and second upper openings 6210a and 6220a, respectively, and the substrate 100 and the first and second portions PT1a and PT2a of the lower hard mask film 610a may be etched simultaneously by the first etching process.

In at least one embodiment, while etching the substrate 100, the lower hard mask film 610a and the second mask pattern 720 remaining on the lower hard mask film 610a may be etched. For example, after the lower opening 6110a is formed, the second mask pattern 720 having the third opening 7200 defining the lower opening 6110a may remain. In these cases, the substrate 100 and the second mask pattern 720 may be etched simultaneously by the first etching process. When the second mask pattern 720 is removed by being completely etched, the lower hard mask film 610a under the second mask pattern 720 may be etched by the first etching process. In these cases, the substrate 100 and the lower hard mask film 610a may be etched simultaneously by the first etching process.

A first lower recess 6121a may be formed by etching the first portion PT1a of the lower hard mask film 610a by the first etching process. An inner surface of the first lower recess 6121a of the lower hard mask film 610a may be substantially coplanar with the inner surface of the first upper opening 6210a of the upper hard mask film 620a. When the first portion PT1a of the lower hard mask film 610a is completely etched, a portion of the first active region AR1 may be exposed by the first lower recess 6121a. The first lower recess 6121a may overlap a second recess region TGR2a to be formed subsequently.

A second lower recess 6122a may be formed by etching the second portion PT2a of the lower hard mask film 610a by the first etching process. The second lower recess 6122a may overlap the second upper opening 6220a. The second lower recess 6122a may be located under the second upper opening 6220a. An inner surface of the second lower recess 6122a may be coplanar with the inner surface of the second upper opening 6220a. When the second portion PT2a of the lower hard mask film 610a is completely etched, a portion of the second active region AR2 may be exposed by the second lower recess 6122a. The second lower recess 6122a may overlap a second gate recess SGRa to be formed subsequently.

While the substrate 100 is etched by the first etching process, a level of a bottom TRB1a of the first recess region TGR1a may gradually decrease. That is, a depth of the first recess region TGR1a may increase. While the first recess region TGR1a is formed, thicknesses of the first and second portions PT1a and PT2a of the lower hard mask film 610a may gradually decrease.

An etch rate of the substrate 100 may differ from an etch rate of the lower hard mask film 610a. In at least one embodiment, the etch rate of the substrate 100 by etching ions may be about three times or more the etch rate of the lower hard mask film 610a by the etching ions. Accordingly, in the first etching process, while the first and second portions PT1a and PT2a of the lower hard mask film 610a are completely etched, the substrate 100 may be etched to a depth of about three times the thicknesses of the first and second portions PT1a and PT2a of the lower hard mask film 610a. However, depending on the design of the image sensor to be implemented, a ratio of the etch rate of the substrate 100 to the etch rate of the lower hard mask film 610 may be set differently. For example, the etch rate of the substrate 100 with respect to the etch rate of the lower hard mask film 610a may be increased to form the deeper first recess region TGR1a. Conversely, the etch rate of the substrate 100 with respect to the etch rate of the lower hard mask film 610a may be decreased to form the shallower first recess region TGR1a.

The first portion PT1a of the lower hard mask film 610a and the substrate 100 located under the first portion PT1a may be sequentially etched by the first etching process and the second etching process. Specifically, the first portion PT1a of the lower hard mask film 610a may be etched by the first etching process to form the first lower recess 6121a, and a portion of the first active region AR1 exposed by the first lower recess 6121a may be sequentially etched by the second etching process. That is, the first etching process and the second etching process may be performed sequentially. However, when an etching target changes from the lower hard mask film 610a to the substrate 100, the etch rate may increase. In at least one embodiment, when the etching target changes from the lower hard mask film 610a to the substrate 100, the etch rate may increase by about three times or more.

The second recess region TGR2a may overlap the first lower recess 6121a. The second recess region TGR2a may be formed by etching a surface of the substrate 100 located under the first lower recess 6121a by the second etching process. The second recess region TGR2a may be formed under the remaining portion of the first upper opening 6210a.

A depth of the first recess region TGR1a formed by the first etching process may be further increased by the second etching process.

An etch rate of the second recess region TGR2a may be the same as (or substantially similar to) that of the first recess region TGR1a. However, a depth of the second recess region TGR2a may be smaller than the depth of the first recess region TGR1a. In other words, a level of a bottom TRB2a of the second recess region TGR2a may be higher than the level of the bottom TRB1a of the first recess region TGR1a.

The second portion PT2a of the lower hard mask film 610a and the substrate 100 located under the second portion PT2a may be sequentially etched by the first etching process and the second etching process. Specifically, the second portion PT2a of the lower hard mask film 610a may be etched by the first etching process to form the second lower recess 6122a, and a portion of the second active region AR2 exposed by the second lower recess 6122a may be sequentially etched by the second etching process. That is, the first etching process and the second etching process may be performed sequentially. However, when an etching target changes from the lower hard mask film 610a to the substrate 100, the etch rate may increase. In at least one embodiment, when the etching target changes from the lower hard mask film 610a to the substrate 100, the etch rate may increase by about three times or more.

The second gate recess SGRa may be formed by etching a surface of the substrate 100 located under the second lower recess 6122a by the second etching process. An etch rate of the second gate recess SGRa may be the same as (or substantially similar to) that of the first gate recess TGRa.

A depth of the second gate recess SGRa may be the same as (or substantially similar to) the depth of the second recess region TGR2a. For example, a level of a bottom SRBa of the second gate recess SGRa may be substantially the same as the level of the bottom TRB2a of the second recess region TGR2a. This may be because the second gate recess SGRa and the second recess region TGR2a are formed simultaneously by the second etching process.

However, a depth of the second gate recess SGRa may be smaller than the depth of the first recess region TGR1a. In other words, the level of the bottom SRBa of the second gate recess SGRa may be higher than the level of the bottom TRB1a of the first recess region TGR1a. This may be because the first recess region TGR1a formed by the first etching process is further etched by the second etching process.

The second recess region TGR2a and the second gate recess SGRa may be formed simultaneously by the second etching process. Specifically, a time period in which the second recess region TGR2a is formed may be substantially the same as a time period in which the second gate recess SGRa is formed.

Furthermore, since the first portion PT1a and the second portion PT2a of the lower hard mask film 610a include the same material and have substantially the same thickness, etching timing of the first portion PT1a of the lower hard mask film 610 may overlap etching timing of the second portion PT2a. Therefore, a time point at which the second recess region TGR2a begins to be formed may be substantially the same as a time point at which the second gate recess SGRa begins to be formed.

The hard mask film 600 may be removed. Specifically, when the first and second gate recesses TGRa and SGRa are formed, the upper hard mask film 620a and the lower hard mask film 610a may be sequentially removed.

As a result, in the first gate recess TGRa, a difference may occur between the depth of the first recess region TGR1a and the depth of the second recess region TGR2a. Specifically, the depth of the first recess region TGR1a may be larger than the depth of the second recess region TGR2a. The depth of the second gate recess SGRa may be substantially the same as the depth of the second recess region TGR2a.

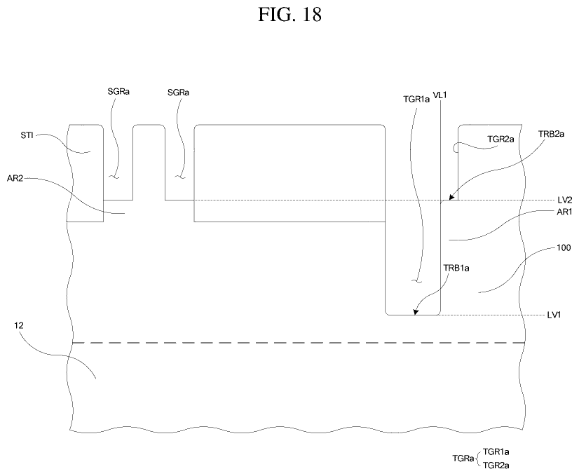

Referring to FIGS. 6 and 18, the manufacturing method may further include forming a gate dielectric film 120 conformally covering inner surfaces of the first and second gate recesses TGRa and SGRa, and forming a transfer gate TGa filling the first gate recess TGRa and a source follower gate SFGa filling the second gate recess SGRa on the gate dielectric film 120.

The manufacturing method may further include forming a floating diffusion region FD in the substrate 100. The forming of the floating diffusion region FD may be performed after the forming of the transfer gate TGa and the source follower gate SFGa. However, the present disclosure is not limited thereto, the forming of the floating diffusion region FD may also be performed before the forming of the transfer gate TGa and the source follower gate SFGa.

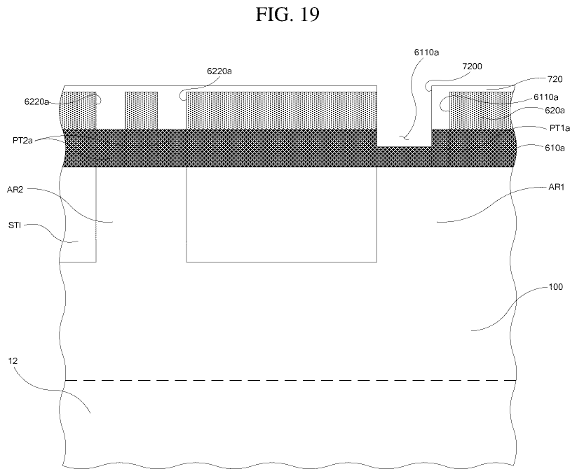

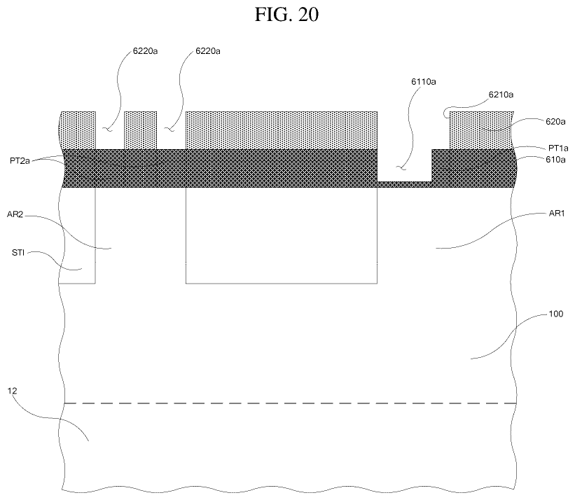

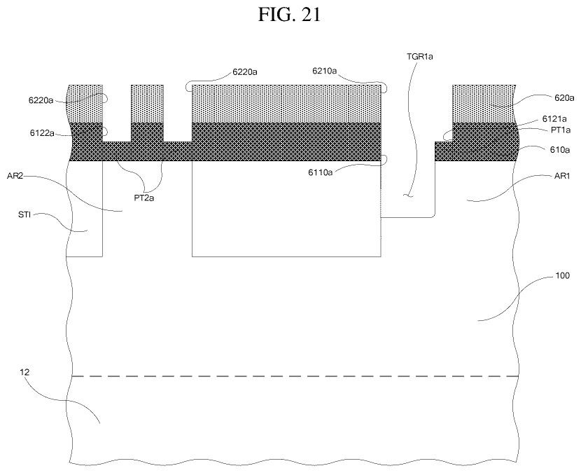

FIGS. 19 to 21 show parts of a manufacturing method of an image sensor according to at least one embodiment of the present disclosure, which are cross-sectional views corresponding to line I-I′ of FIG. 5.

Referring to FIGS. 19 to 21, in one embodiment, in forming the lower opening 6110a in the lower hard mask film 610, the timing at which the lower opening 6110a is completely formed may differ from the timing at which the second mask pattern 720 is removed by being completely etched. That is, the second mask pattern 720 may be removed before the lower opening 6110a is completely formed. However, conversely, as described above, the second mask pattern 720 may remain even after the lower opening 6110a is completely formed.

In at least one embodiment, when the second mask pattern 720 is removed before the lower opening 6110a is completely formed, the first portion PT1a of the lower hard mask film 610 may be etched simultaneously while the lower opening 6110a is formed. Furthermore, the second portion PT2a of the lower hard mask film 610 may also be etched simultaneously while the lower opening 6110a is formed.

While the first and second portions PT1a and PT2a of the lower hard mask film 610 are etched, a portion of the lower hard mask film 610 corresponding to the first recess region TGR1a may be completely etched to form the lower opening 6110a. A portion of the first active region AR1 may be exposed by the lower opening 6110a. The exposed portion of the substrate 100 may be immediately etched by the first etching process. That is, the first and second portions PT1a and PT2a of the lower hard mask film 610 and the substrate 100 may be etched simultaneously by the first etching process.

Therefore, by changing a timing point at which the second mask pattern 720 is removed, a difference in depth between the first recess region TGR1a and the second recess region TGR2a may be controlled.

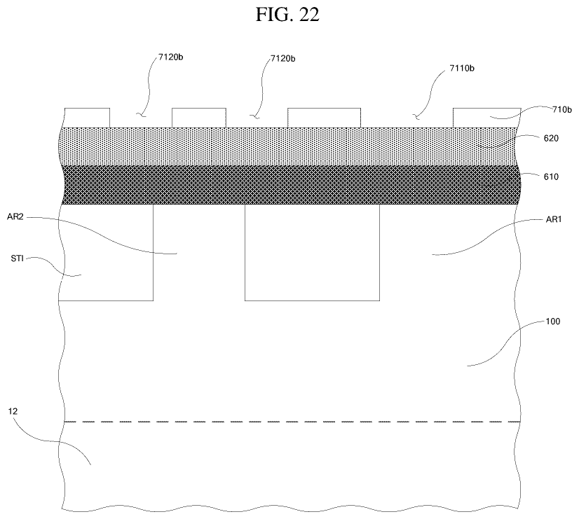

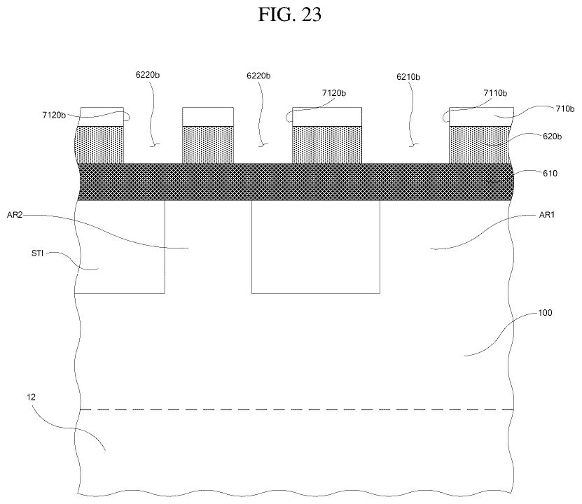

FIGS. 22 to 27 show a manufacturing method of an image sensor according to at least one embodiment of the present disclosure, which are cross-sectional views corresponding to line I-I′ of FIG. 5, Referring to FIGS. 22 and 23, first and second upper openings 6210b and 6220b may be formed in the upper hard mask film 620. The first and second upper openings 6210b and 6220b may be formed by patterning the upper hard mask film 620. Specifically, the forming of the first and second upper openings 6210b and 6220b in the upper hard mask film 620 may include forming a first mask pattern 710b having first and second openings 7110b and 7120b that define the first and second upper openings 6210b and 6220b on the upper hard mask film 620, and etching the upper hard mask film 620 using the first mask pattern 710b as an etching mask.

A portion of the first opening 7110b of the first mask pattern 710b may overlap the first active region AR1. The remaining portion of the first opening 7110b of the first mask pattern 710b may overlap the shallow trench isolation STI. A portion of the second opening 7120b of the first mask pattern 710b may overlap the second active region AR2. The remaining portion of the second opening 7120b of the first mask pattern 710b may overlap the shallow trench isolation STI.

In at least one embodiment, the etching of the upper hard mask film 620 using the etching selectivity between the upper hard mask film 620 and the lower hard mask film 610 may be performed until an upper surface of the lower hard mask film 610 is exposed. Therefore, the first upper opening 6210b may expose a portion of the lower hard mask film 610, and the second upper opening 6220b may expose the other portion of the lower hard mask film 610.

In at least one embodiment, the second opening 7120b of the first mask pattern 710b may include a pair of second openings 7120b that are spaced apart from each other. When the upper hard mask film 620 is etched using the first mask pattern 710b having the pair of second openings 7120b as an etching mask, a pair of second upper openings 6220b may be formed in the upper hard mask film 620. The pair of second upper openings 6220b may expose other portions of the lower hard mask film 610.

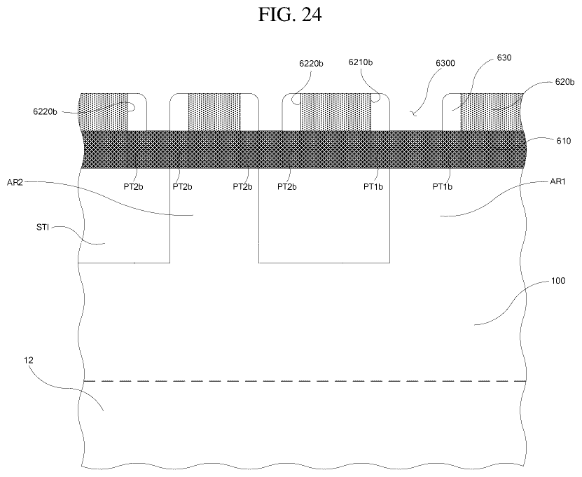

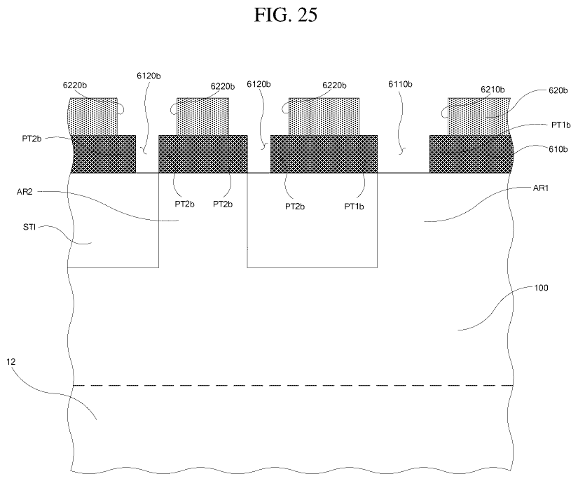

Referring to FIGS. 24 and 25, a lower opening may be formed in the lower hard mask film 610. The lower opening may include first and second lower openings 6110b and 6120b. The first mask pattern 710b may be removed before the first and second lower openings 6110b and 6120b are formed.

The forming of the lower opening may include forming spacers 630 on inner surfaces of the first and second upper openings 6210b and 6220b, and etching the lower hard mask film 610 using the upper hard mask film 620b and the spacers 630 as etching masks.

The spacers 630 may cover the inner surfaces of the first and second upper openings 6210b and 6220b. The spacer 630 covering the inner surface of the first upper opening 6210b may overlap the shallow trench isolation STI and the first active region AR1. The spacer 630 covering the inner surface of the second upper opening 6220b may overlap the shallow trench isolation STI and the second active region AR2.

A portion of the lower hard mask film 610 covered by the spacer 630 disposed on the inner surface of the first upper opening 6210b may be referred to as a first portion PT1b. A portion of the lower hard mask film 610 covered by the spacer 630 disposed on the inner surface of the second upper opening 6220b may be referred to as a second portion PT2b.

In at least one embodiment, the spacer 630 may include a pair of spacers 630 covering the inner surfaces of a pair of second upper openings 6220b.

The spacer 630 may have an opening 6300. The opening 6300 of the spacer 630 covering the inner surface of the first upper opening 6210b may overlap the first active region AR1. A portion of the lower hard mask film 610 may be exposed by the opening 6300 of the spacer 630 covering the inner surface of the first upper opening 6210b. The opening 6300 of the spacer 630 covering the inner surface of the second upper opening 6220b may overlap the shallow trench isolation STI. The other portion of the lower hard mask film 610 may be exposed by the opening 6300 of the spacer 630 covering the inner surface of the second upper opening 6220b.

The upper hard mask film 620 having the first and second upper openings 6210b and 6220b, and the spacers 630 covering the inner surfaces of the first and second upper openings 6210b and 6220b may be used as etching masks. The first lower opening 6110b may be formed by etching the portion of the lower hard mask film 610 exposed by the opening 6300 of the spacer 630 covering the inner surface of the first upper opening 6210b. The second lower opening 6120b may be formed by etching the other portion of the lower hard mask film 610 exposed by the opening 6300 of the spacer 630 covering the inner surface of the second upper opening 6220b. The first lower opening 6110b and the second lower opening 6120b may be formed simultaneously.

The first lower opening 6110b may expose a surface of the substrate 100. Specifically, the first lower opening 6110b may expose a portion of the first active region AR1. The second lower opening 6120b may expose the shallow trench isolation STI. Specifically, the second lower opening 6120b may expose the shallow trench isolation STI adjacent to the second active region AR2.

The manufacturing method may further include removing the spacer 630. The spacers 630 may be removed after the first and second lower openings 6110b and 6120b are completely formed. When the spacer 630 covering the inner surface of the first upper opening 6210b is removed, the first portion PT1b of the lower hard mask film 610b may be exposed. When the spacer 630 covering the inner surface of the second upper opening 6220b is removed, the second portion PT2b of the lower hard mask film 610b may be exposed.

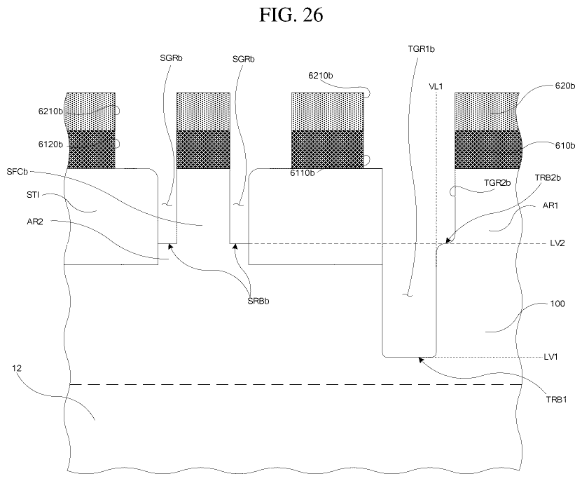

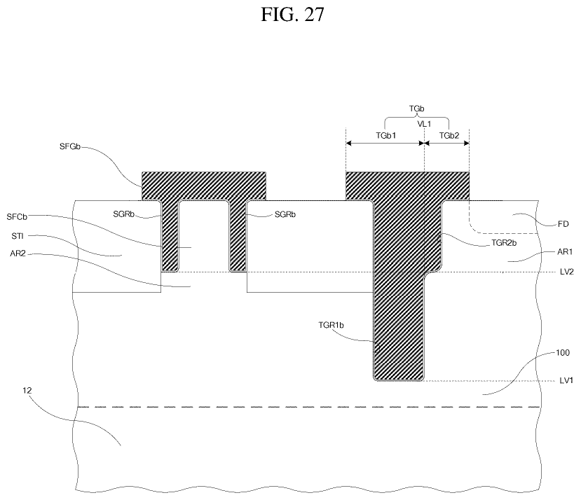

Referring to FIGS. 26 and 27, first and second gate recesses TGRb and SGRb may be formed in the substrate 100. Specifically, the first and second gate recesses TGRb and SGRb may be formed by etching the substrate 100 by the first etching process using the upper hard mask film 620b having the first and second upper openings 6210b and 6220b as an etching mask.

A first recess region TGR1b may be formed in the substrate 100. The first recess region TGR1b may be formed by etching a portion of the first active region AR1 exposed by the first lower opening 6110b by the first etching process. Therefore, the first recess region TGR1b may be formed under the first lower opening 6110b.

In at least one embodiment, the lower hard mask film 610b may be etched while etching the substrate 100 by the first etching process. Specifically, in the first etching process, while the portion of the first active region AR1 exposed by the first lower opening 6110b is etched, the lower hard mask film 610b having the first lower opening 6110b may also be etched. More specifically, as the spacers 630 are removed, the first and second portions PT1b and PT2b of the lower hard mask film 610b may be exposed by the first and second upper openings 6210b and 6220b, respectively, and the substrate 100 and the first and second portions PT1b and PT2b of the lower hard mask film 610b may be etched simultaneously by the first etching process.

The first lower opening 6110b may be formed by etching the first portion PT1b of the lower hard mask film 610b by the first etching process. An inner surface of the first lower opening 6110b of the lower hard mask film 610b may be substantially coplanar with an inner surface of the first upper opening 6210b of the upper hard mask film 620b. When the first portion PT1b of the lower hard mask film 610b is completely etched, a portion of the shallow trench isolation STI and the first active region AR1 may be exposed by the first lower opening 6110b. The exposed portion of the first active region AR1 may overlap the second recess region TGR2b to be formed subsequently.

The second lower opening 6120b may be formed by etching the second portion PT2b of the lower hard mask film 610b by the first etching process. An inner surface of the second lower opening 6120b of the lower hard mask film 610b may be substantially coplanar with an inner surface of the second upper opening 6220b of the upper hard mask film 620b. When the second portion PT2b of the lower hard mask film 610b is completely etched, a portion of the shallow trench isolation STI and the second active region AR2 may be exposed by the second lower opening 6120b. The exposed portion of the second active region AR2 may overlap the second gate recess SGRb to be formed subsequently.

While the substrate 100 is etched by the first etching process, a level of a bottom TRB1b of the first recess region TGR1b may gradually decrease. That is, a depth of the first recess region TGR1b may increase. While the first recess region TGR1b is formed, thicknesses of the first and second portions PT1b and PT2b of the lower hard mask film 610b may gradually decrease.

An etch rate of the substrate 100 may differ from an etch rate of the lower hard mask film 610b. In at least one embodiment, the etch rate of the substrate 100 by etching ions may be about three times or more the etch rate of the lower hard mask film 610b by the etching ions. Accordingly, while the first and second portions PT1b and PT2b of the lower hard mask film 610b are completely etched, the substrate 100 may be etched to a depth of about three times the thicknesses of the first and second portions PT1b and PT2b of the lower hard mask film 610b. However, depending on the design of the image sensor to be implemented, a ratio of the etch rate of the substrate 100 to the etch rate of the lower hard mask film 610b may be set differently. For example, the etch rate of the substrate 100 with respect to the etch rate of the lower hard mask film 610b may be increased to form the first recess region TGR1b deeper. Conversely, the etch rate of the substrate 100 with respect to the etch rate of the lower hard mask film 610b may be decreased to form the first recess region TGR1b shallower.

The first portion PT1a of the lower hard mask film 610b and the substrate 100 located under the first portion PT1a may be sequentially etched by the first etching process and the second etching process. Specifically, the first portion PT1b of the lower hard mask film 610b may be etched by the first etching process to form the first lower opening 6110b, and a portion of the first active region AR1 exposed by the first lower opening 6110b may be sequentially etched by the second etching process. That is, the first etching process and the second etching process may be performed sequentially. However, when an etching target changes from the lower hard mask film 610b to the substrate 100, the etch rate may increase. In one embodiment, when the etching target changes from the lower hard mask film 610b to the substrate 100, the etch rate may increase by about three times or more.

The second portion PT2b of the lower hard mask film 610b and the substrate 100 located under the second portion PT2b may be sequentially etched by the first etching process and the second etching process. Specifically, the second portion PT2b of the lower hard mask film 610b may be etched by the first etching process to form the second lower opening 6120b, and a portion of the second active region AR2 exposed by the second lower opening 6120b may be sequentially etched by the second etching process. That is, the first etching process and the second etching process may be performed sequentially. However, when an etching target changes from the lower hard mask film 610b to the substrate 100, the etch rate may increase. In at least one embodiment, when the etching target changes from the lower hard mask film 610b to the substrate 100, the etch rate may increase by about three times or more.

However, the shallow trench isolation STI exposed by the first and second lower openings 6110b and 6120b may not be substantially etched by the first etching process or the second etching process.

As a result, the first gate recess TGRb may be formed in the first active region AR1. Specifically, the first recess region TGR1b may be formed in a portion of the first active region AR1 exposed by the first lower opening 6110b, and the second recess region TGR2b may be formed in the other portion of the first active region AR1 covered by the first portion PT1b of the lower hard mask film 610b. A second gate recess SGRb may be formed in the second active region AR2. Specifically, the second gate recess SGRb may be formed in a portion of the second active region AR2 covered by the second portion PT2b of the lower hard mask film 610b.

The second gate recess SGRb may be formed by etching a surface of the substrate 100 located under the second lower opening 6120b by the second etching process. An etch rate of the second gate recess SGRb may be substantially the same as that of the first gate recess TGRb.

A depth of the second gate recess SGRb may be the same as (or substantially similar to) the depth of the second recess region TGR2b. Specifically, a level of a bottom SRBb of the second gate recess SGRb may be the same as (or substantially similar to) the level of the bottom TRB2b of the second recess region TGR2b. However, a depth of the second gate recess SGRb may be smaller than the depth of the first recess region TGR1b. In other words, the level of the bottom SRBb of the second gate recess SGRb may be higher than the level of the bottom TRB1b of the first recess region TGR1b.

In at least one embodiment, the bottom TRB2b of the second recess region TGR2b may be an inflection point. In other words, a shape extending from one side to the other side starting from the bottom TRB2b of the second recess region TGR2b may change from a concave shape to a convex shape or from the convex shape to the concave shape.

The second recess region TGR2b and the second gate recess SGRb may be formed simultaneously. Specifically, a time period in which the second recess region TGR2b is formed and a time period in which the second gate recess SGRb is formed may be substantially the same.

Furthermore, since the first portion PT1b and the second portion PT2b of the lower hard mask film 610b include the same material and have substantially the same thickness, an etching time period of the first portion PT1b of the lower hard mask film 610b may overlap an etching time period of the second portion Pt2b. Therefore, a time point at which the second recess region TGR2b begins to be formed may be substantially the same as (or substantially similar to) a time point at which the second gate recess SGRb begins to be formed.

The hard mask film 600 may be removed. Specifically, when the first and second gate recesses TGRb and SGRb are formed, the upper hard mask film 620b and the lower hard mask film 610b may be sequentially removed.

As a result, in the first gate recess TGRb, a difference may occur between the depth of the first recess region TGR1b and the depth of the second recess region TGR2b. Specifically, the depth of the first recess region TGR1b may be larger than the depth of the second recess region TGR2b. The depth of the second gate recess SGRb may be substantially the same as (or substantially similar to) the depth of the second recess region TGR2b.

The transfer gate TGb may fill the first gate recess TGRb formed in the first active region AR1. The transfer gate TGb may protrude upward from an upper surface of the substrate 100. The transfer gate TGb may extend planarly on the upper surface of the substrate 100. Through this, the transfer gate TGb may cover an upper surface of the first active region AR1 and an upper surface of the shallow element isolation pattern STI.

The source follower gate SFGb may fill the second gate recess SGRb formed in the second active region AR2. In one embodiment, the source follower gate SFGb may fill a pair of second gate recesses SGRb. The source follower gate SFGb may protrude upward from the upper surface of the substrate 100. The source follower gate SFGb may extend planarly on the upper surface of the substrate 100. Therefore, the source follower gate SFGb may cover a channel region SFCb and the upper surface of the shallow element isolation pattern STI.

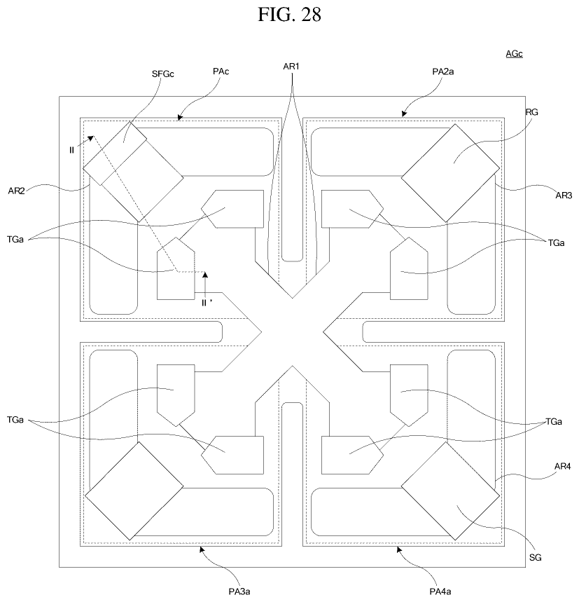

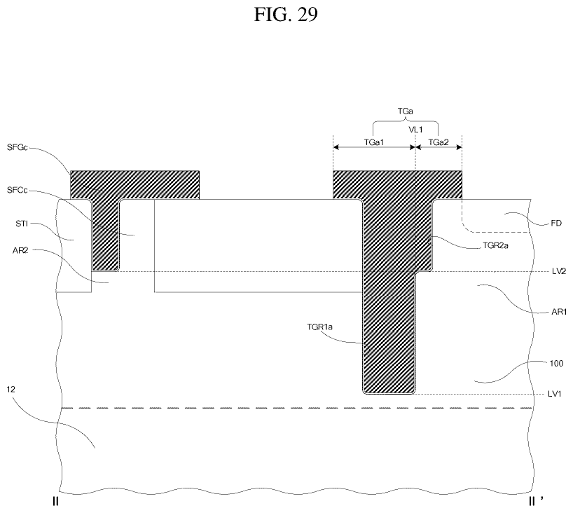

FIG. 28 is a plan view of an active portion group AGc according to at least one embodiment of the present disclosure. FIG. 29 is a cross-sectional view taken along line II-II′ of FIG. 28.

Referring to FIGS. 28 and 29, in one embodiment, a single second gate recess SGRc may be provided in the second active region AR2. Specifically, one side surface of the second gate recess SGRc may be defined by the shallow trench isolation STI. The other side surface of the second gate recess SGRc may be defined by the second active region AR2.

A channel region SFCc may be defined by the second gate recess SGRc and the shallow trench isolation STI. Specifically, the channel region SFCc may be defined between the other side surface of the second gate recess SGRc and the shallow trench isolation STI. The channel region SFCc may be controlled by a source follower gate SFGc.

The source follower gate SFGc may fill the second gate recess SGRc. The source follower gate SFGc may protrude upward from an upper surface of the substrate 100. The source follower gate SFGc may extend planarly on the upper surface of the substrate 100. Therefore, the source follower gate SFGc may cover upper surfaces of the channel region SFCc and the shallow trench isolation STI.

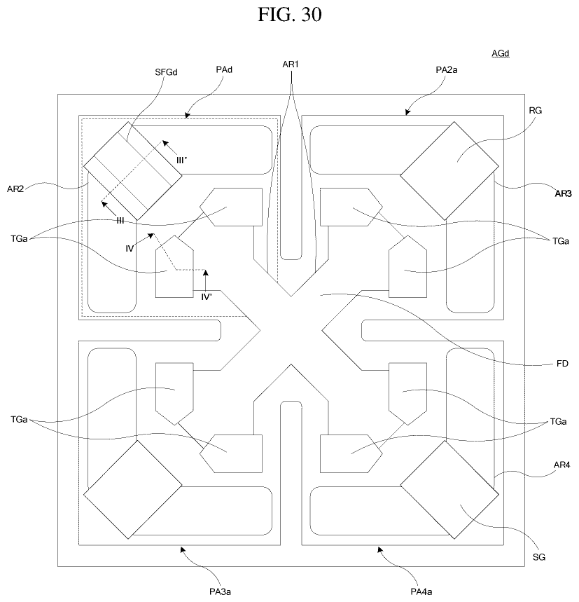

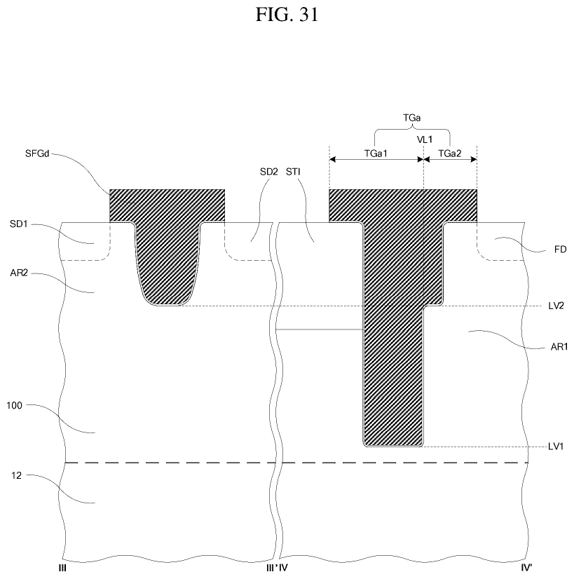

FIG. 30 is a plan view of an active region group Agd according to at least one embodiment of the present disclosure. FIG. 31 is a cross-sectional view taken along line III-III′ of FIG. 30.

Referring to FIGS. 30 and 31, in at least one embodiment, a single second gate recess SGRd may be provided in the second active region AR2. Specifically, the second gate recess SGRd may be provided in a concave shape between a first source/drain pattern SD1 and a second source/drain pattern SD2.

A channel region SFCd may be defined in a concave shape along a bottom surface of the second gate recess SGRd. The channel region SFCd may be controlled by a source follower gate SFGd.

The source follower gate SFGd may fill the second gate recess SGRd. The source follower gate SFGd may protrude upward from an upper surface of the substrate 100. The source follower gate SFGd may extend planarly on the upper surface of the substrate 100. Therefore, the source follower gate SFGd may cover the second active region AR2 between the first and second source/drain patterns SD1 and SD2.

FIG. 32 is a cross-sectional view of an image sensor according to at least one embodiment of the present disclosure.

Referring to FIG. 32, an image sensor according to some embodiments of the present disclosure may include a photoelectric conversion layer 10, a light-transmitting layer 20, and a first wiring layer 30. The photoelectric conversion layer 10 may be disposed between the light-transmitting layer 20 and the first wiring layer 30. The photoelectric conversion layer 10 may include a first substrate 100. The first substrate 100 may have a first surface 100a and a second surface 100b that face each other. In some embodiments, the first substrate 100 may be a semiconductor substrate (for example, a silicon (Si) substrate, a germanium (Ge) substrate, or a silicon-germanium (SiGe) substrate).

A deep element isolation pattern DTI may be provided in the first substrate 100 to define a plurality of pixel active portions PA.

A shallow element isolation pattern STI may be provided in the first substrate 100 to define at least one active region in each of the pixel active portions PA. The shallow element isolation pattern STI may be adjacent to the first surface 100a of the first substrate 100. The first surface 100a of the first substrate 100 may correspond to one surface of the above-mentioned substrate 100.

A photoelectric conversion region 12 may be respectively provided in the pixel active portion PA. The first substrate 100 may be doped with dopants having a first conductivity type, and the photoelectric conversion regions 12 may be doped with dopants having a second conductivity type different from the first conductivity type. For example, the first conductivity type may be a P-type, and the second conductivity type may be an N-type.

A transfer gate TGa may be provided in the corresponding active region of each of the pixel active portions PA. A gate dielectric film may be disposed between the transfer gate TGa and the corresponding active region. In some embodiments, the transfer gate TGa may fill a first gate recess formed in the corresponding active region. In these cases, the gate dielectric film may extend to be disposed between the transfer gate TG and an inner surface of the fist gate recess.

A source follower gate SFGa may be provided in an active region of any one of the pixel active regions PA. The gate dielectric film may be disposed between the source follower gate SFGa and the corresponding active region. In some embodiments, the source follower gate SFGa may fill a second gate recess formed in the corresponding active region. In this case, the gate dielectric film may extend to be disposed between the source follower gate SFGa and an inner surface of the second gate recess.

In some embodiments, other gates (not shown) may be provided on the active regions with the corresponding gate dielectric film therebetween. The other gates may include a reset gate and a selection gate. In some embodiments, the other gates may further include a gate performing another function (e.g., a dual conversion gain gate). Source/drain regions may be provided at both sides of each of the other gates. The other gates may be provided on the corresponding active regions of each of the pixel active portions PA. Alternatively, the other gates may be provided on the corresponding active regions of the pixel active portions PA of the pixels sharing the other gates.

As described above, the transfer gate TGa, the source follower gate SFGa, and the other gates may be provided on the first surface 100a of the first substrate 100. However, the embodiments of the present disclosure are not limited thereto. In some embodiments, the transfer gate TGa and the source follower gate SFGa may be provided on the first surface 100a of the first substrate 100, and the other gates may be provided on an additional substrate (e.g., a third substrate). The additional substrate may have a third surface facing the first surface 100a and a fourth surface opposite to the third surface. The other gates (for example, the reset gate RG and the selection gate SG) may be provided on the third surface or the fourth surface of the additional substrate with an additional gate dielectric film (for example, a third interlayer insulating film) interposed therebetween. Hereafter, for convenience of explanation, the embodiment in which the transfer gate TGa, the source follower gate SFGa, and the other gates are provided on the first surface 100a of the first substrate 100 will be sequentially described as an example.

The deep element isolation pattern DTI, the shallow element isolation pattern STI, the photoelectric conversion regions 12, the floating diffusion regions FD, and the transfer gates TGa may be included in the photoelectric conversion layer 10.

The light-transmitting layer 20 may be provided on the second surface 100b of the first substrate 100. The light-transmitting layer 20 may include a transmission insulating film 22, a grid pattern 26, a protective film 24, color filters CF1, CF2, and CF3, and micro lenses ML.

The transmission insulating film 22 may cover the second surface 100b of the first substrate 100. The transmission insulating film 22 may have a single-layered structure or a multi-layered structure. In some embodiments, the transmission insulating film 22 may include a fixed charge film and/or an anti-reflection film.

The fixed charge film may have negative fixed charges. Therefore, holes may be accumulated at a location adjacent to the fixed charge film, for example, at an interface between the fixed charge film and the first substrate 100 and/or in a portion of the first substrate 100 adjacent to the second surface 100b. As a result, the fixed charge film may effectively reduce a dark current and/or a white spot. In some embodiments, the fixed charge film may be made of a metal oxide or a metal fluoride containing at least one of hafnium Hf, zirconium Zr, aluminum Al, tantalum Ta, titanium Ti, yttrium Y, a lanthanide, a combination thereof, and/or the like. For example, the fixed charge film may be made of a hafnium oxide, an aluminum oxide, and/or a combination thereof.

The anti-reflection film may reduce or minimize reflection of light incident on the second surface 100b. For example, the anti-reflection film may include at least one of a titanium oxide, a silicon nitride, a silicon oxide, a hafnium oxide, and/or the like. When the transmission insulating film 22 includes the fixed charge film and the anti-reflection film, the fixed charge film may be in contact with the second surface 100b of the first substrate 100, and the anti-reflection film may be disposed on the fixed charge film. However, the embodiments of the present disclosure are not limited thereto. In some embodiments, the transmission insulating film 22 may include any one of the fixed charge film and the anti-reflection film, and/or may further include an additional insulating film.

The grid pattern 26 may have a grid shape with openings in a plan view. In some embodiments, the openings of the grid pattern 26 may vertically overlap the pixel active portions PA, respectively. The grid pattern 26 may guide incident light so that the incident light is incident on the photoelectric conversion regions 12. In some embodiments, the grid pattern 26 may include a light-shielding pattern and/or a low refractive pattern. For example, the light-shielding pattern may include at least one of titanium, titanium nitride, tantalum, tantalum nitride, or tungsten. The low refractive pattern may have a refractive index lower than the refractive indices of the color filters CF1, CF2, and CF3. For example, the low refractive pattern may include an organic material.

The protective film 24 may conformally cover a surface (e.g., an upper surface and side surfaces) of the grid pattern 26 and the transmission insulating film 22 exposed by the openings of the grid pattern 26. In some embodiments, the protective film 24 may be made of an insulating material having a high dielectric constant. For example, the protective film 24 may include an aluminum oxide, a hafnium oxide, and/or the like.

The color filters CF1, CF2, and CF3 may fill the openings of the grid pattern 26. The color filters CF1, CF2, and CF3 may be disposed on the protective film 24. The color filters CF1, CF2, and CF3 may vertically overlap the photoelectric conversion regions 12. In some embodiments, the color filters CF1, CF2, and CF3 may include a first color filter CF1 having a first color, a second color filter CF2 having a second color, and a third color filter CF3 having a third color. In at least one embodiment, the first color may be one of red, green, and blue colors, the second color may be another of red, green, and blue colors, and the third color may be the remaining one of red, green, and blue colors. Alternatively, the first color may be one of magenta, cyan, and yellow colors, the second color may be another of magenta, cyan, and yellow colors, and the third color may be the remaining one of magenta, cyan, and yellow colors. However, the embodiments of the present disclosure are not limited thereto. The first to third colors may be various other colors.

As shown in FIG. 32, each of the color filters CF1, CF2, and CF3 may vertically overlap a corresponding one of the photoelectric conversion regions 12. However, the embodiments of the present disclosure are not limited thereto. In some embodiments, each of the color filters CF1, CF2, and CF3 may vertically overlap the plurality of photoelectric conversion regions 12 that are adjacent to each other. The photoelectric conversion regions 12 corresponding to each of the color filters CF1, CF2, and CF3 may be arranged in a matrix form. For example, the corresponding photoelectric conversion regions 12 may be arranged in a 2×2 matrix form, a 3×3 matrix form, or a 4×4 matrix form.

The micro lenses ML may be provided on the color filters CF1, CF2, and CF3. The micro lenses ML may concentrate incident light. As shown in FIG. 32, the micro lenses ML may vertically overlap the photoelectric conversion regions 12. Alternatively, each of the micro lenses ML may vertically overlap the plurality of photoelectric conversion regions 12 that are adjacent to each other. For example, each of the micro lenses ML may vertically overlap the photoelectric conversion regions 12 arranged in a 2×2 matrix form, a 3 ×3 matrix form, or a 4 ×4 matrix form. In some embodiments, the number of photoelectric conversion regions 12 overlapping at least one of the micro lenses ML may differ from the number of photoelectric conversion regions 12 overlapping at least another one of the micro lenses ML. For example, the at least one micro lens ML may vertically overlap a pair of photoelectric conversion regions 12 that are adjacent to each other, and the at least another one micro lens ML may vertically overlap a single photoelectric conversion region 12 or the photoelectric conversion regions 12 that are adjacent to each other.

Each of the micro lenses ML may have a convex shape facing upward from a cross-sectional perspective. In some embodiments, each of the micro lenses ML may have a circular shape or an elliptical shape in a plan view. The micro lenses ML may be made of, e.g., a light-transmitting resin and/or polymer.

Although not shown, an additional protective film may be provided on surfaces of the micro lenses ML. The additional protective film may protect the micro lenses ML and transmit light. The additional protective film may be made of an organic material and/or an inorganic material. For example, the additional protective film may include at least one of a silicon oxide, a silicon nitride, a silicon oxynitride, a silicon carbide, a silicon carbo-oxide, a silicon carbo-nitride, a silicon carbo-oxynitride, an aluminum oxide, a zinc oxide, a hafnium oxide, a combination therefore, and/or the like.

As shown in FIG. 32, the grid pattern 26 may be vertically aligned with the deep trench isolation DTI, and the micro lens ML and the color filter CF1 or CF2 may be vertically aligned with the corresponding photoelectric conversion region 12. However, the embodiments of the present disclosure are not limited thereto.

The first wiring layer 30 may be provided on the first surface 100a of the first substrate 100. The first wiring layer 30 may cover the first surface 100a of the first substrate 100 and include first insulating films ILD1 and first wiring lines ICL1. The first wiring lines ICL1 may be provided between the first interlayer insulating films ILD1. The first wiring lines ICL1 may be electrically connected to pixel transistors (e.g., the transfer transistor, the reset transistor, the source follower transistor, and the selection transistor) and/or electrically connect the pixel transistors through first contact plugs.

The image sensor may further include a second substrate 200, peripheral transistors PTR formed on an upper surface of the second substrate 200, and a second wiring layer 40 provided on the upper surface of the second substrate 200 to cover the peripheral transistors PTR. The second substrate 200 may be a semiconductor substrate such as a silicon substrate, germanium substrate, or silicon-germanium substrate. The second wiring layer 40 may include second interlayer insulating films ILD2 and second wiring lines ICL2 between the second interlayer insulating films ILD2. The second wiring lines ICL2 may be electrically connected to the peripheral transistors PTR or electrically connect the peripheral transistors PTR through second contact plugs. The second wiring lines ICL2 and the peripheral transistors PTR may configure a peripheral circuit (e.g., a row decoder, a row driver, a column decoder, a timing generator, a correlated double sampler, an analog-to-digital converter, and/or an input/output buffer) of the image sensor.

The second wiring layer 40 may be disposed between the first wiring layer 30 and the second substrate 200. In some embodiments, the lowermost one of the first interlayer insulating films ILD1 may be bonded to the uppermost one of the second interlayer insulating film ILD2.

FIG. 33 is a cross-sectional view of an image sensor according to at least one embodiment of the present disclosure.

Referring to FIG. 33, an image sensor may include a light-transmitting layer 20, a photoelectric conversion layer 10, and a first wiring layer 30. The light-transmitting layer 20 may be the same as (or substantially similar to) the light-transmitting layer 20 of FIG. 31. The photoelectric conversion layer 10 may include a transmission insulating film 22, a first substrate 100, a deep trench isolation DTI, photoelectric conversion regions 12, a shallow trench isolation STI, transfer gates TG, and floating diffusion regions FD. The first wiring layer 30 may include first wiring lines ICL1, first interlayer insulating films ILD1, and the first bonding pads (not shown).

The image sensor may further include a second substrate 200 and a second wiring layer ICL2 on the second substrate 200. However, the image sensor may further include second bonding pads (no reference numerals) provided in the uppermost of second interlayer insulating films ILD2.

The image sensor may include a third substrate 300, gates RG and SG on the third substrate 300, and a third wiring layer 50 provided on the third substrate 300.

The third substrate 300 may be a semiconductor substrate (for example, a silicon Si substrate, a germanium Ge substrate, a silicon-germanium SiGe substrate, etc.). Each of the gates RG and SG may be disposed on the third substrate 300 with a gate dielectric film interposed therebetween. Source/drain regions (not shown) may be provided in the third substrate 300 at both sides of each of the gates RG and SG. The third substrate 300 may have a third surface 300a and a fourth surface 300b that are opposite to each other. The third surface 300a may correspond to one surface of the above-described substrate 100.

A second shallow element isolation pattern STI2 may be provided in the third substrate 300 to define active regions. The second shallow element isolation pattern STI2 may be adjacent to the third surface 300a of the third substrate 300.

The third wiring layer 50 may be provided on the third surface 300a of the third substrate 300. The third wiring layer 50 may cover the third surface 300a of the third substrate 300. The third wiring layer 50 may include third interlayer insulating films ILD3, third wiring lines (not shown), and at least one third bonding pad (not shown).

The third wiring layer 50 may be in contact with the first wiring layer 30. The third wiring layer 50 may be electrically connected to the first wiring layer 30. The lowermost one of the first interlayer insulating films ILD1 may be bonded to the uppermost one of the third interlayer insulating films ILD3.

However, according to at least one embodiment, at least any one of the reset gate RG, the selection gate SG may be provided on the third substrate 300.

The reset gate RG and the selection gate SG may be provided on the third surface 300a or the fourth surface 300b of the third substrate 300.

According to some embodiments of the present disclosure, a first gate recess and a second gate recess can be formed in a substrate by etching a lower hard mask film having a lower opening and the substrate using an upper hard mask film having first and second upper openings as an etching mask. Accordingly, a manufacturing method of an image sensor can be simplified. That is, manufacturing processes can be reduced, and manufacturing costs can be reduced.

According to some embodiments of the present disclosure, since the first gate recess and the second gate recess can be formed using the upper hard mask film having the first and second upper openings as an etching mask, misalignment between the first gate recess and the second gate recess can be minimized or prevented.

According to some to embodiments of the present disclosure, a transfer gate can include a deep first gate portion and a shallow second gate portion, and the second gate portion can be provided between the first gate portion and a floating diffusion region. Accordingly, the photocharge transfer performance of the transfer gate can be improved.

The above-described contents are specific embodiments for implementing the present disclosure. In addition to the above-described embodiments, the present disclosure will also include embodiments that may be simply changed in design or easily modified. In addition, the present disclosure will also include technologies that may be easily modified and implemented using the embodiments. Therefore, the scope of the present disclosure should not be limited to the above-described embodiments, but should be defined by the appended claims and their equivalents.

What is claimed is:

1. A manufacturing method of an image sensor, comprising:
forming a first gate recess in a first active region of a substrate using a first etching process;
forming a second gate recess in a second active region of the substrate using a second etching process; and
forming a gate dielectric film on an inner surface of the first gate recess and an inner surface of the second gate recess,
wherein the second etching process is also performed on at least a portion of the first gate recess such that a depth of the at least a portion of the first gate recess becomes larger, and such that the depth of the at least a portion of the first gate recess, in the substrate, is larger than a depth of the second gate recess.

2. The manufacturing method of claim 1, wherein the forming a first gate recess comprises:
forming a lower hard mask film and an upper hard mask film sequentially on the substrate;
forming a first upper opening and a second upper opening in the upper hard mask film;
forming a lower opening overlapping a portion of the first upper opening in the lower hard mask film; and
etching the substrate through the first etching process using the lower hard mask having the lower opening as an etching mask.

3. The manufacturing method of claim 2, wherein after the forming the lower opening
a remaining portion of the first upper opening exposes an upper surface of a first portion of the lower hard mask film, and
the second upper opening exposes an upper surface of a second portion of the lower hard mask film, and
wherein the forming of the first gate recess further includes etching the first portion and the second portion of the lower hard mask film through the first etching process using the upper hard mask film as an etching mask.

4. The manufacturing method of claim 3, wherein after the etching the first portion and the second portion of the lower hard mask film the lower hard mask film includes:
a first lower recess formed by etching the first portion of the lower hard mask film; and
a second lower recess formed by etching the second portion of the lower hard mask film, and
wherein the forming of the second gate recess includes etching the substrate through the second etching process using the upper hard mask film having the first upper opening and the second upper opening and the lower hard mask film having the first lower recess and the second lower recess as etching masks.

5. The manufacturing method of claim 4, wherein after the etching the first portion and the second portion of the lower hard mask film
the first gate recess includes a first recess region and a second recess region, and
wherein the first recess region is formed under the portion of the first upper opening overlapping the lower opening, and
the second recess region is formed under the remaining portion of the first upper opening.

6. The manufacturing method of claim 5, wherein a depth of the first recess region is larger than a depth of the second recess region.

7. The manufacturing method of claim 5, wherein
a bottom of the second recess region and a bottom of the second gate recess are at a substantially same level.

8. The manufacturing method of claim 2, wherein the forming of the lower opening comprises:
forming a mask pattern on the upper hard mask film having the first and second upper openings, the mask pattern having an opening defining the lower opening and covering at least a portion of the first and second portions of the lower hard mask film; and
etching the lower hard mask film using the mask pattern as an etching mask.

9. The manufacturing method of claim 8, wherein the etching the substrate results in the first gate recess including a first recess region and a second recess region, and
wherein the second recess region is formed by etching the mask pattern, the first portion of the lower hard mask film, and the substrate sequentially, and
the second gate recess is formed by etching the mask pattern, the second portion of the lower hard mask film, and the substrate sequentially.

10. A manufacturing method of an image sensor, comprising:
forming a lower hard mask film and an upper hard mask film sequentially on a substrate;
forming a first upper opening and a second upper opening in the upper hard mask film;
forming a first lower opening in the lower hard mask film such that the first lower opening overlaps a portion of the first upper opening; and
forming a first gate recess and a second gate recess in the substrate by etching the lower hard mask film having the first lower opening and etching the substrate using the upper hard mask film having the first and second upper openings as an etching mask.

11. The manufacturing method of claim 10, wherein after the forming the first gate recess
the first gate recess includes a first recess region and a second recess region, and
wherein the first recess region is formed under the portion of the first upper opening overlapping the first lower opening, and
the second recess region is formed under a remaining portion of the first upper opening.

12. The manufacturing method of claim 11, wherein the forming of the first lower opening comprises:
forming spacers on inner surfaces of the first and second upper openings; and
etching the lower hard mask film using the upper hard mask film and the spacers as etching masks.

13. The manufacturing method of claim 12, further comprising,
before forming the lower hard mask film, defining a first active region and a second active region by forming a shallow element isolation pattern in the substrate,
wherein forming the first lower opening includes forming a second lower opening in the lower hard mask layer such that the second lower opening overlaps the second upper opening,
the first lower opening exposes a portion of the first active region,
the second lower opening exposes the shallow element isolation pattern,
the first gate recess is formed in the first active region, and
the second gate recess is formed in the second active region.

14. The manufacturing method of claim 13, wherein after the forming the first gate recess and the second gate recess
the first gate recess includes a first recess region and a second recess region,
the first recess region is formed in the portion of the first active region exposed by the first lower opening,
the second recess region is formed in another portion of the first active region, and
a level of a bottom of the second recess region is higher than a level of a bottom of the first recess region and substantially the same as a level of a bottom of the second gate recess.

15. The manufacturing method of claim 14, further comprising:
forming a floating diffusion region in the substrate;
forming a gate dielectric film conformally covering inner surfaces of the first and second gate recesses; and
forming a transfer gate filling the first gate recess and a source follower gate filling the second gate recess on the gate dielectric film,
wherein the second recess region is formed between the first recess region and the floating diffusion region.

16. An image sensor comprising:
a shallow element isolation pattern in a substrate, the shallow element isolation pattern defining a first active region and a second active region;
a transfer gate filling a first gate recess in the first active region;
a source follower gate filling a second gate recess in the second active region; and
a gate dielectric film between the transfer gate and an inner surface of the first gate recess and between the source follower gate and an inner surface of the second gate recess,
wherein the first gate recess includes
a first recess region, and a second recess region shallower than the first recess region, and
wherein a bottom of the second recess region and a bottom of the second gate recess are at a substantially same level.

17. The image sensor of claim 16, wherein
the bottom of the second recess region includes at least one of a flat surface or an inflection point.

18. The image sensor of claim 16, wherein
the second gate recess includes a pair of second gate recesses in the second active region, the pair of second gate recesses spaced apart from each other, and
a fin-shaped channel region between the pair of second gate recesses.

19. The image sensor of claim 16, wherein
one side surface of the second gate recess is defined by the shallow element isolation pattern and the other side surface of the second gate recess is defined by the second active region, and
a channel region, configured to be controlled by the source follower gate, is adjacent to the other side surface of the second gate recess and a portion of an upper surface of the second active region.

20. The image sensor of claim 16, wherein
a channel region under the source follower gate is concave along a bottom surface of the second gate recess.
